(19) United States
(12) Patent Application Publication
(10) Pub. No.: US 2025/0151553 A1
(43) Pub. Date: May 8, 2025

(54) PAD STRUCTURE AND DISPLAY DEVICE HAVING THE SAME

(71) Applicant: Samsung Display Co., Ltd., Yongin-si (KR)

(72) Inventors: KIYONG KIM, Yongin-si (KR); HEEJU WOO, Yongin-si (KR); CHOLONG WON, Yongin-si (KR); HYUNGBIN CHO, Yongin-si (KR)

(21) Appl. No.: 18/915,589

(22) Filed: Oct. 15, 2024

(30) Foreign Application Priority Data
Nov. 6, 2023 (KR) 10-2023-0151549

(51) Int. Cl. H10K 59/131; H10K 59/95

(52) U.S. Cl. CPC H10K 59/131; H10K 59/95

(57) ABSTRACT

A display device includes a base layer including a display area including a light emitting element, and a non-display area which is adjacent to the display area and includes a pad, and a signal line connecting the light emitting element to the pad. In the non-display area, the pad includes a lower conductive pattern on the base layer, a first pattern on the lower conductive pattern and including a first photosensitive material, an upper conductive pattern on the lower conductive pattern and overlapping the first pattern, and a second pattern on the first pattern and comprising a second photosensitive material different from the first photosensitive material.

This application claims priority to Korean Patent Application No. 10-2023-0151549, filed on Nov. 6, 2023, and all the benefits accruing therefrom under 35 U.S.C. § 119, the disclosure of which is incorporated by reference herein in its entirety.

### BACKGROUND

### 1. Field

The present disclosure relates to a display device. More particularly, the present disclosure relates to a display device with improved structural stability in a pad area.

### 2. Description of Related Art

A display device includes a display area activated in response to electrical signals. The display device senses external inputs applied thereto through the display area and displays images to provide information to outside the display device, such as to a user of the display device.

The display device includes a display panel and a circuit board. The display panel is connected to a main board via the circuit board. A driving chip is mounted on the display panel.

### SUMMARY

The present disclosure provides a display device including a pad with improved structural stability.

Embodiments of the invention provide a display device including a base layer including a display area and a non-display area adjacent to the display area, lower insulating layers disposed on the base layer, a light emitting element disposed in the display area, a pad disposed in the non-display area, and a signal line connected to the light emitting element and the pad.

The pad may include a lower conductive pattern disposed on the lower insulating layers, a first pattern disposed on the lower conductive pattern and including a first photosensitive material, an upper conductive pattern disposed on the lower conductive pattern and overlapping at least a portion of the first pattern, and a second pattern disposed on the first pattern and including a second photosensitive material different from the first photosensitive material.

The first photosensitive material may be a polymer with a negative photosensitivity.

The second photosensitive material may be a polymer with a positive photosensitivity or a metal material with the positive photosensitivity.

The second pattern may include an upper surface with a curvature.

A width of the second pattern in a direction in which the pads are arranged decreases as a distance from the base layer increases.

The second pattern may be disposed on the upper conductive pattern.

The upper conductive pattern may be disposed between the first pattern and the second pattern.

The upper conductive pattern may cover an upper surface of the first pattern, side surfaces of the first pattern, and at least a portion of an upper surface of the lower conductive pattern.

The display device may further include a metal layer covering an upper surface of the second pattern and at least a portion of side surfaces of the upper conductive pattern, and an upper insulating layer covering the metal layer and at least a portion of the upper conductive pattern.

The metal layer may include a metal layer upper portion covering the second pattern and a metal layer side portion disposed on the side surface of the upper conductive pattern, and the metal layer side portion may be in contact with the upper insulating layer.

The metal layer may further include a metal layer tip portion disposed on the upper insulating layer and protruded in a direction in which the pads are arranged.

The display device may further include a driving chip providing a data signal to the light emitting element and a bump disposed under the driving chip and being in contact with the metal layer.

The bump, the metal layer, the upper conductive pattern, and the lower conductive pattern may be electrically connected to each other.

A shape of the metal layer upper portion may be deformed due to a pressure applied thereto by the bump in a direction toward the base layer.

An anchor portion which is defined when at least a portion of the metal layer side portion is bent and recessed in a direction toward the first pattern may be formed on the metal layer side portion.

A separation space may be defined between the driving chip and the base layer.

The separation space may be filled with a non-conductive adhesive.

The metal layer may include a first metal layer including titanium (Ti), a second metal layer disposed on the first metal layer and including aluminum (Al), and a third metal layer disposed on the second metal layer and including titanium (Ti).

The upper conductive pattern may include a first upper pattern layer including titanium (Ti), a second upper pattern layer disposed on the first upper pattern layer and including aluminum (Al), and a third upper pattern layer disposed on the second upper pattern layer and including titanium (Ti).

The lower conductive pattern may include a first lower pattern layer including titanium (Ti), a second lower pattern layer disposed on the first lower pattern layer and including aluminum (Al), and a third lower pattern layer disposed on the second lower pattern layer and including titanium (Ti).

The metal layer may cover at least a portion of an upper surface of the upper conductive pattern.

The display device may further include a sub-pattern.

The metal layer may cover the second pattern and at least a portion of the sub-pattern.

One side surface of the first pattern may be disposed spaced apart from the sub-pattern with the upper conductive pattern interposed therebetween when viewed in a plane substantially parallel to the base layer.

A portion of the upper conductive pattern, which covers the other side surface opposite to the one side surface of the first pattern, may be at least partially covered by the metal layer.

At least a portion of a side surface of the upper conductive pattern may be exposed without being covered by the sub-pattern.

The portion of the upper conductive pattern exposed without being covered by the sub-pattern may be in contact with at least a portion of the metal layer.

The display device may further include a first sub-pattern and a second sub-pattern.

One side surface of the first pattern may be spaced apart from the first sub-pattern with the upper conductive pattern interposed therebetween when viewed in a cross-section, and the other side surface of the first pattern, which is opposite to the one side surface of the first pattern, may be spaced apart from the second sub-pattern with the upper conductive pattern interposed therebetween when viewed in the cross-section.

Portions of the side surface of the upper conductive pattern may be exposed respectively without being covered by the first sub-pattern and the second sub-pattern.

The portions of the upper conductive pattern exposed respectively without being covered by the first sub-pattern and the second sub-pattern may be in contact with at least a portion of the metal layer.

The upper conductive pattern may cover an upper surface of the second pattern, side surfaces of the first pattern, and at least a portion of an upper surface of the lower conductive pattern.

The second pattern may be disposed between the first pattern and the upper conductive pattern.

The display device may further include a bump which is directly in contact with the upper conductive pattern.

The display device may further include a metal layer which covers at least a portion of the upper conductive pattern.

The display device may further include a first sub-pattern and a second sub-pattern.

One side surface of the first pattern may be spaced apart from the first sub-pattern with the upper conductive pattern interposed therebetween when viewed in a cross-section, the other side surface of the first pattern, which is opposite to the one side surface of the first pattern, may be spaced apart from the second sub-pattern with the upper conductive pattern interposed therebetween when viewed in the cross-section.

Each of the first sub-pattern and the second sub-pattern has a width which increases as it goes down when viewed in the cross-section (e.g., in a downward direction).

According to the above, the display panel is bonded to electronic components without using an anisotropic conductive film. Accordingly, even though the signal pads are densely arranged in the pad area, a defect, such as short circuit, caused by conductive balls, is prevented, and thus, the reliability of the display device with high resolution is improved.

### BRIEF DESCRIPTION OF THE DRAWINGS

The above and other advantages of the present disclosure will become readily apparent by reference to the following detailed description when considered in conjunction with the accompanying drawings where:

FIG. 1A is a perspective view of an electronic device according to an embodiment of the present disclosure;

FIG. 1B is an exploded perspective view of an electronic device according to an embodiment of the present disclosure;

FIG. 2 is a cross-sectional view of a display device according to an embodiment of the present disclosure;

FIG. 3A is a plan view of a display panel according to an embodiment of the present disclosure;

FIG. 3B is an enlarged cross-sectional view of a display panel according to an embodiment of the present disclosure;

FIG. 4A is a cross-sectional view of an input sensing unit according to an embodiment of the present disclosure;

FIG. 4B is a plan view of an input sensing unit according to an embodiment of the present disclosure;

FIG. 4C is an enlarged cross-sectional view of a display device taken along line I-I′ of FIG. 4B;

FIG. 5 is an enlarged exploded perspective view of a pad area of a display device according to an embodiment of the present disclosure;

FIGS. 6A and 6B are cross-sectional views of a portion of a display device taken along line II-II′ of FIG. 5; and

FIGS. 7A to 7E are cross-sectional views of a portion of a display device taken along line II-II′ of FIG. 5.

### DETAILED DESCRIPTION

The present disclosure may be variously modified and realized in many different forms, and thus specific embodiments will be exemplified in the drawings and described in detail hereinbelow. However, the present disclosure should not be limited to the specific disclosed forms, and be construed to include all modifications, equivalents, or replacements included in the spirit and scope of the present disclosure.

In the present disclosure, it will be understood that when an element (or area, layer, or portion) is referred to as being related to another element such as being “on”, “connected to” or “coupled to” another element or layer, it can be directly on, connected or coupled to the other element or layer or intervening elements or layers may be present. In contrast, when an element (or area, layer, or portion) is referred to as being related to another element such as being “directly on”, “directly connected to” or “directly coupled to” another element or layer, no intervening element or layer is present therebetween.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” may include any and all combinations of one or more of the associated listed items.

Like numerals refer to like elements throughout. For example, within the Figures and the text of the disclosure, a reference number indicating a singular form of an element may also be used to reference a plurality of the singular element. In the drawings, the thickness, ratio, and dimension of components are exaggerated for effective description of the technical content.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described with reference to accompanying drawings.

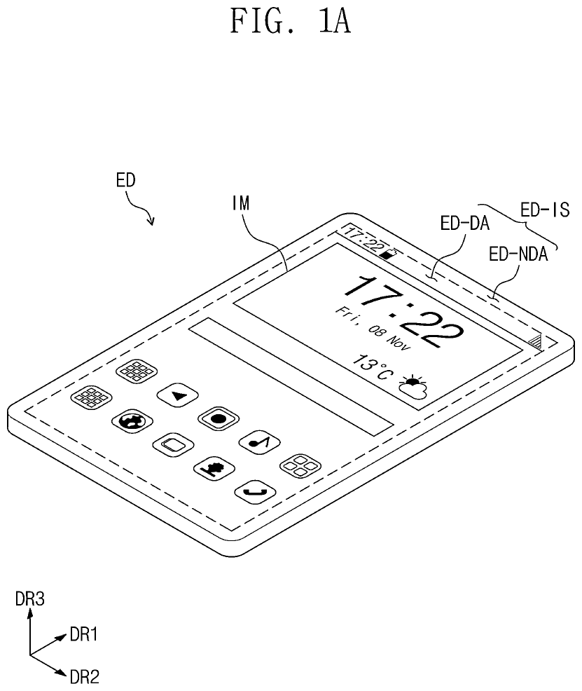

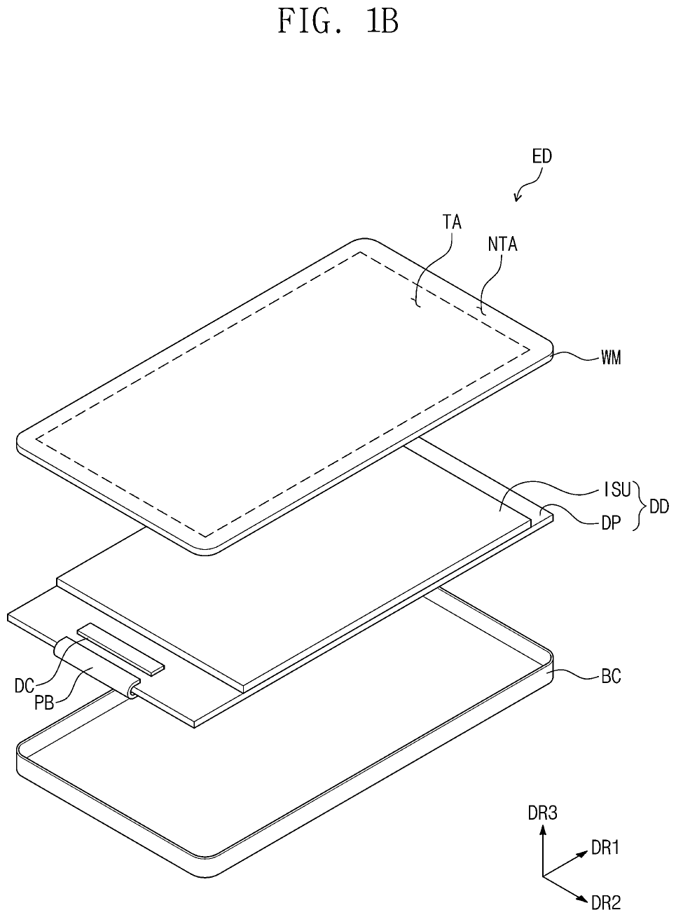

FIG. 1A is a perspective view of an electronic device ED according to an embodiment of the present disclosure. FIG. 1B is an exploded perspective view of the electronic device ED according to an embodiment of the present disclosure.

FIGS. 1A and 1B show a mobile phone as a representative example of the electronic device ED, however, the present disclosure should not be limited thereto or thereby. The electronic device ED may be applied to a large-sized display device, such as a television set, a monitor, etc., and a small and medium-sized display device, such as a tablet computer, a smart watch, a navigation unit, etc. In addition, the electronic device ED may be provided in the form of a foldable electronic device.

Referring to FIG. 1A, the electronic device ED may display an image IM through (or at) a display surface ED-IS. FIG. 1A illustrates icon images as a representative example of the image IM.

The display surface ED-IS may be substantially parallel to a plane defined by a first direction DR1 and a second direction DR2 crossing each other. A third direction DR3 may indicate a direction intersecting the display surface ED-IS, such as a normal line direction of the display surface ED-IS, e.g., a thickness direction of the electronic device ED.

In the following descriptions, an expression “when viewed in a plane” or “in a plane” may mean a state of being viewed in (or along) the third direction DR3. Front (or upper) and rear (or lower) surfaces of members included in the electronic device ED may be defined with respect to the third direction DR3.

The display surface ED-IS may include a display area ED-DA and a non-display area ED-NDA. The display area ED-DA may be an area (e.g., a planar area) through which the image IM is displayed and/or in which an external input to the electronic device ED is sensed. The non-display area ED-NDA may be an area in which the image IM is not displayed. The non-display area ED-NDA may be defined adjacent to the display area ED-DA. FIG. 1A shows a structure in which the non-display area ED-NDA surrounds the display area ED-DA. However, the present disclosure should not be limited thereto or thereby, and the non-display area ED-NDA may be defined adjacent to one side of the display area ED-DA or may be omitted.

When the electronic device ED is provided in the form of the foldable electronic device, the electronic device ED may include a folding area and non-folding areas spaced apart from each other with the folding area interposed therebetween. The folding area may be an area at which the electronic device ED is foldable such as to be folded with respect to an imaginary folding axis defined in the electronic device ED.

When the electronic device ED is folded, the electronic device ED may be inwardly folded (in-folding) to allow the non-folding areas to face each other along the thickness direction when completely folded (e.g., completely in-folded), or may be outwardly folded (out-folding) to allow the non-folding areas to face in opposite directions to each other when completely folded (e.g., completely out-folded).

Referring to FIG. 1B, the electronic device ED may include a window WM, a display device DD, and a case BC. Although not shown in FIG. 1B, when the electronic device ED is the foldable electronic device, the electronic device ED may further include a mechanical structure (e.g., a hinge) to control a folding operation thereof. In addition, the case BC may be provided in plural according to the number of the non-folding areas.

The window WM may be disposed above the display device DD, such as in an image display direction or a light emission direction of the display device DD. The window WM may protect the display device DD and may transmit the image IM (refer to FIG. 1A) provided from the display device DD to the outside of the electronic device ED. The window WM may include a glass or plastic material. The window WM may have a single-layer or multi-layer structure. As an example, the window WM may include a plurality of plastic films attached to each other by an adhesive or a glass substrate combined with a plastic film.

The window WM may include a transmission area TA (e.g., a light transmission area) and a non-transmission area NTA (e.g., a light blocking area).

The transmission area TA may overlap (or correspond to) the display area ED-DA (refer to FIG. 1A) and may have a shape (e.g., a planar shape) corresponding to that of the display area ED-DA. The transmission area TA may have a high light transmittance and thus may transmit the image IM (refer to FIG. 1A) displayed in the display device DD to the outside of the electronic device ED.

The non-transmission area NTA may overlap the non-display area ED-NDA (refer to FIG. 1A) and may have a shape corresponding to that of the non-display area ED-NDA. The non-transmission area NTA may have a relatively low light transmittance compared to that of the transmission area TA. That is, the light transmittance at the non-transmission area NTA may be lower than the light transmittance of the transmission area TA. However, the present disclosure should not be limited thereto or thereby, and the non-transmission area NTA may be omitted.

The display device DD may be disposed under the window WM. The display device DD may generate the image IM (refer to FIG. 1A) and/or may sense an external input to the electronic device ED.

The display device DD may include a display panel DP and an input sensing unit ISU which is disposed on the display panel DP. Although not shown in figures, the display device DD may further include an anti-reflective member disposed on the input sensing unit ISU. The anti-reflective member may include a polarizer and a retarder or may include a color filter and a black matrix.

The input sensing unit ISU may include one of a capacitive sensor, an optical sensor, an ultrasonic sensor, and an electromagnetic induction sensor. The input sensing unit ISU may be formed (or provided) on the display panel DP through successive processes, or may be attached to an upper portion of the display panel DP by a separate member like an adhesive layer after being separately manufactured (or provided) from the display panel DP.

The display panel DP may have a configuration which substantially generates the image IM (refer to FIG. 1A). The display panel DP may be a light emitting type display panel which self-emits light. For instance, the display panel DP may be an organic light emitting display panel, an inorganic light emitting display panel, an organic-inorganic light emitting display panel, a quantum dot display panel, a micro light emitting diode (micro-LED) display panel, or a nano-LED display panel. Hereinafter, the organic light emitting display panel will be described as a representative example of the display panel DP, however, the present disclosure should not be limited thereto or thereby.

The display device DD may further include a driving chip DC and a circuit board PB. FIG. 1B shows a structure in which the driving chip DC is mounted on the display panel DP, however, should not be limited thereto or thereby.

The driving chip DC may generate a driving signal necessary for an operation of the display panel DP in response to a control signal applied thereto from the circuit board PB.

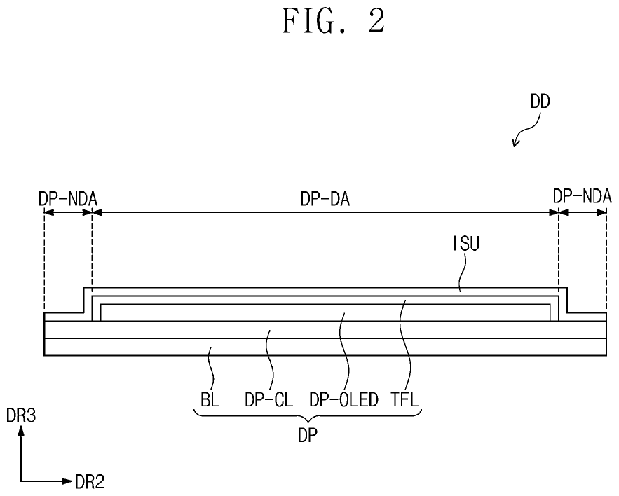

FIG. 1B shows the structure in which the circuit board PB is bent at a bending area thereof and including a portion of the circuit board PB which is disposed on a rear surface of the display panel DP. However, the present disclosure should not be limited thereto or thereby. According to an embodiment, a portion of the display panel DP at which the circuit board PB is attached to the display panel DP may be bent at a bending area of the display panel DP to allow the driving chip DC to face downward (e.g., in a direction away from the window WM). In this case, a non-display area DP-NDA (refer to FIG. 2) of the display panel DP may be bent at a bending area thereof. The circuit board PB may be disposed at one end of a base layer BL of the display panel DP (refer to FIG. 2) and may be connected to a circuit element layer DP-CL of the display panel DP (refer to FIG. 2).

In the above descriptions, the mobile phone terminal is shown as the electronic device ED, but the electronic device ED according to the present disclosure may be described as a device which includes two or more electronic components bonded to each other. As an example, the electronic device ED may include only the display panel DP and the driving chip DC which is mounted on the display panel DP. Hereinafter, the electronic device ED will be described with a focus on the bonding structure between the display panel DP and the driving chip DC which is mounted on the display panel DP.

FIG. 2 is a cross-sectional view of the display device DD according to an embodiment of the present disclosure.

Referring to FIG. 2, the display device DD may include the display panel DP and the input sensing unit ISU which is disposed on the display panel DP.

The display panel DP may include the base layer BL, the circuit element layer DP-CL disposed on the base layer BL, a display element layer DP-OLED disposed on the circuit element layer DP-CL, and an encapsulation layer TFL disposed on the display element layer DP-OLED.

The display panel DP may include a display area DP-DA and the non-display area DP-NDA. The display area DP-DA of the display panel DP may correspond to the display area ED-DA (refer to FIG. 1A) and the transmission area TA (refer to FIG. 1B) of the electronic device ED, and the non-display area DP-NDA of the display panel DP may correspond to the non-display area ED-NDA (refer to FIG. 1A) and the non-transmission area NTA (refer to FIG. 1B) of the electronic device ED.

The base layer BL may be disposed at a lowermost position of the display panel DP and may provide a base surface on which components of the display panel DP are disposed. The base layer BL may include a synthetic resin layer. The synthetic resin layer may include a thermosetting resin. In particular, the synthetic resin layer may include a polyimide-based resin, however, should not be limited thereto or thereby. The synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. The base layer BL may include a glass substrate, a metal substrate, or an organic/inorganic composite material substrate.

The base layer BL may have a structure in which organic layers are alternately stacked with inorganic layers. As an example, the base layer BL may have a structure in which a first organic layer containing polyimide, a first inorganic layer disposed on the first organic layer, a second organic layer containing polyimide and disposed on the first inorganic layer, and a second inorganic layer disposed on the second organic layer are sequentially stacked, however, should not be particularly limited.

The circuit element layer DP-CL may include a plurality of insulating layers and a circuit element. The insulating layers may include at least one inorganic layer and at least one organic layer. The circuit element may include signal lines and a driving circuit. The insulating layer, a semiconductor layer, and a conductive layer may be formed by coating and deposition processes. Then, the insulating layer, the semiconductor layer, and the conductive layer may be selectively patterned by a photolithography process and an etching process. A semiconductor pattern, a conductive pattern, and the signal line of the circuit element layer DP-CL may be formed through the above-mentioned process.

Herein, patterns disposed on (or in) the same layer may be formed through the same process. The expression “The patterns are formed through the same process.”, as used herein, means that the patterns include the same material and have the same stack structure. For example, as being in a same layer, elements may be formed in a same process and/or include a same material as each other, elements may be respective portions of a same material layer, elements may be on a same layer by forming an interface with a same underlying or overlying layer, etc., without being limited thereto.

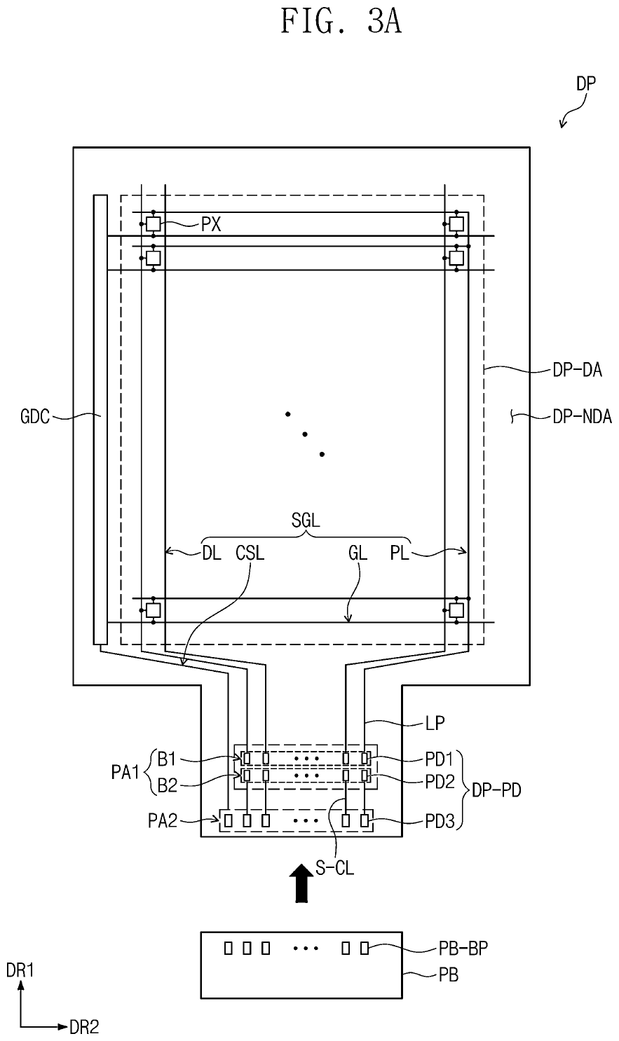

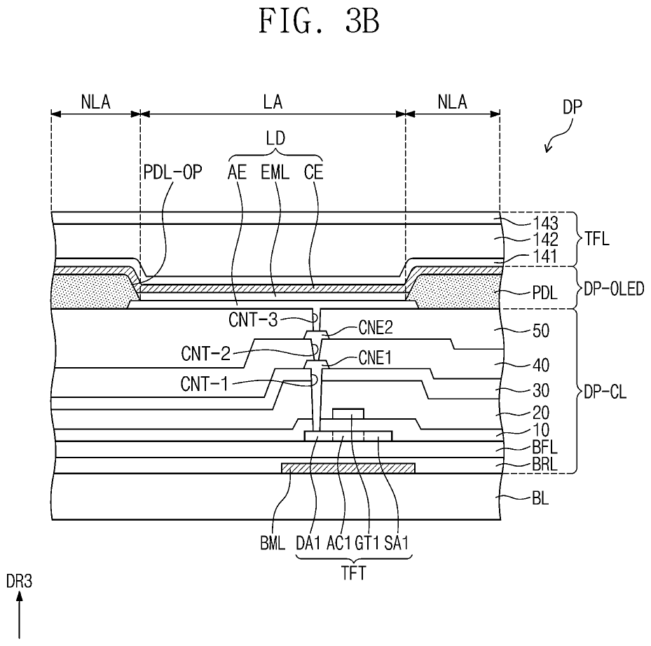

The display element layer DP-OLED may include a pixel definition layer PDL (refer to FIG. 3B) and a light emitting element LD (refer to FIG. 3B).

The encapsulation layer TFL may be disposed on the display element layer DP-OLED and may cover the display element layer DP-OLED. The encapsulation layer TFL may prevent moisture and oxygen from entering the display element layer DP-OLED. The encapsulation layer TFL may have a stack structure of an inorganic layer/organic layer/inorganic layer.

The input sensing unit ISU may be disposed directly on the display panel DP. In the present disclosure, the expression “A component A is disposed directly on a component B.” means that no intervening elements are present between the component A and the component B. Layers or components which are disposed ‘directly’ relative to each other may contact each other, may form an interface therebetween, etc.

FIG. 3A is a plan view of the display panel DP according to an embodiment of the present disclosure.

Referring to FIG. 3A, the display panel DP may include a plurality of pixels PX, a gate driving circuit GDC, a plurality of signal lines SGL, and a plurality of signal pads DP-PD.

The pixels PX may be arranged in the display area DP-DA. Each pixel PX among the pixels PX may include a light emitting element LD and a pixel driving circuit which is connected to the light emitting element LD. In the present embodiment, the light emitting element LD may be an organic light emitting element.

The gate driving circuit GDC may be disposed in the non-display area DP-NDA of the display panel DP. The gate driving circuit GDC may sequentially output gate signals as electrical signals, to gate lines GL. The gate driving circuit GDC (e.g., the non-display area DP-NDA) may include a transistor having layers or patterns formed through the same process, e.g., a low temperature polycrystalline silicon (LTPS) process, a low temperature polycrystalline oxide (LTPO) process, or a hybrid oxide and polycrystalline silicon (HOP) process, as layers or patterns of a transistor of the pixel PX (e.g., the display area DP-DA).

However, the driving circuit of the display panel DP should not be limited to the gate driving circuit GDC, and the display panel DP may further include another driving circuit to apply a light emission control signal to the pixels PX. As an example, the display panel DP may include a light emission driving circuit.

The signal lines SGL may be disposed in the display area DP-DA and in the non-display area DP-NDA, such as to extend from the display area DP-DA to the non-display area DP-NDA. The signal lines SGL may include the gate lines GL, data lines DL, a power line PL, and a control signal line CSL. Each of the gate lines GL may be connected to a corresponding pixel PX among the pixels PX, and each of the data lines DL may be connected to a corresponding pixel PX among the pixels PX. The power line PL may be connected to the pixels PX. The control signal line CSL may provide control signals as electrical signals, to the gate driving circuit GDC.

Each of the signal lines SGL may include a line part LP. Although not shown in FIG. 3A, the signal lines SGL may further include a pad part. The line part LP may overlap the display area DP-DA and the non-display area DP-NDA, such as extending from the display area DP-DA to be disposed in the non-display area DP-NDA. The pad part may be connected to or defined by an end (e.g., a distal end or a terminal end) of the line part LP. The distal end may be disposed at an end portion of the display panel DP (e.g., the lowermost portion of the display panel DP in FIG. 3A, for example).

The signal pads DP-PD may include first pads PD1, second pads PD2, and third pads PD3.

A first pad area PA1 and a second pad area PA2 may be disposed in the non-display area DP-NDA. The first pad area PA1 in which both the first pads PD1 and the second pads PD2 are disposed may overlap the driving chip DC (refer to FIG. 1B). The second pad area PA2 in which the third pads PD3 are disposed may overlap the circuit board PB.

The first pad area PA1 and the second pad area PA2 may be spaced apart from each other in (or along) the first direction DR1.

The first pad area PA1 may include a first area B1 (e.g., a first sub-area) in which the first pads PD1 are disposed and a second area B2 (e.g., a second sub-area) in which the second pads PD2 are disposed.

An area (e.g., a planar area) in which the first pads PD1 and the second pads PD2 are disposed may be referred to as the first pad area PA1, and an area (e.g., a planar area) in which the third pads PD3 are disposed may be referred to as the second pad area PA2.

In the present embodiment, the first pads PD1 may be arranged in one row in the first area B1, where the row extends along the second direction DR2. However, the arrangement of the first pads PD1 in the first area B1 should not be limited thereto or thereby. As an example, the first pads PD1 may be arranged in two or more rows in the first area B1, each row being extended along the second direction DR2.

Referring to FIG. 3A, the second area B2 may be defined below the first area B1, such as closer to the distal end of the display panel DP. The second pads PD2 arranged in the second area B2 may be connected to the third pads PD3 as display panel pads arranged in the second pad area PA2, via connection signal lines S-CL.

The circuit board PB may include substrate bumps PB-BP as circuit board bumps. The substrate bumps PB-BP may be arranged in the second direction DR2. The substrate bumps PB-BP of the circuit board PB may be connected to the third pads PD3 of the second pad area PA2. The circuit board bumps may respectively correspond to the display panel pads.

FIG. 3B is a cross-sectional view of the display panel DP according to an embodiment of the present disclosure. FIG. 3B shows a cross-section of the display panel DP, which correspond to one light emitting area LA and a portion of the non-light-emitting area NLA. The light emitting area LA and the non-light-emitting area NLA will be described later.

The display panel DP may include the base layer BL, the circuit element layer DP-CL disposed on the base layer BL, the display element layer DP-OLED disposed on the circuit element layer DP-CL, and the encapsulation layer TFL disposed on the display element layer DP-OLED.

For the convenience of explanation, FIG. 3B shows only one transistor TFT as a representative example of the pixel driving circuit, however, the present disclosure should not be limited thereto or thereby. According to an embodiment, the pixel PX may include a plurality of transistors within the pixel driving circuit.

In the present embodiment, the circuit element layer DP-CL may include a barrier layer BRL, a buffer layer BFL, first, second, third, fourth, and fifth lower insulating layers 10, 20, 30, 40, and 50, a transistor TFT, a first connection electrode CNE1, and a second connection electrode CNE2, however, the present disclosure should not be limited thereto or thereby. The barrier layer BRL or the buffer layer BFL may be omitted, one or more layers of the first, second, third, fourth, and fifth lower insulating layers 10, 20, 30, 40, and 50 may be omitted, or the circuit element layer DP-CL may further include other insulating layers. As used herein, more than one among the aforementioned barrier, buffer and insulating layers may be collectively referred to as ‘an insulating layer.’

The barrier layer BRL may be disposed on the base layer BL. The barrier layer BRL may prevent a foreign substance from entering from the outside. The barrier layer BRL may include a silicon oxide layer and/or a silicon nitride layer. Each of the silicon oxide layer and the silicon nitride layer may be provided in plural, and the plural silicon oxide layers may be alternately stacked with the plural silicon nitride layers.

The barrier layer BRL may include a light blocking layer BML as a light blocking pattern therein. The light blocking layer BML may block or absorb an external light to prevent an active AC1 of the transistor TFT described later from being photo-degraded by external light traveling thereto. Accordingly, a reliability of the display panel DP may be improved.

The buffer layer BFL may be disposed on the barrier layer BRL. The buffer layer BFL may improve an adhesive force between the semiconductor pattern of the transistor TFT and the base layer BL and/or between a conductive pattern and the base layer BL. The buffer layer BFL may include a silicon oxide layer and/or a silicon nitride layer.

The semiconductor pattern of the transistor TFT may be disposed on the buffer layer BFL. The semiconductor pattern may include polycrystalline silicon, however, should not be limited thereto or thereby. According to an embodiment, the semiconductor pattern may include an amorphous silicon or metal oxide.

FIG. 3B shows a portion of the semiconductor pattern within the semiconductor layer, and the semiconductor pattern may be further disposed in other areas of the display panel DP when viewed in a cross-section. The semiconductor pattern may include a first region and a second region. The first region may be doped with an N-type dopant or a P-type dopant and may have a relatively high conductivity as compared to that of the second region. The first region may substantially correspond to (or function as) an electrode or a signal line which transmits an electrical signal. The second region may be a non-doped region or a region doped at a concentration lower than that of the first region. The second region may substantially correspond to an active (or a channel) of the transistor.

Within the semiconductor layer, a drain DA1, the active AC1, and a source SA1 may be disposed on the buffer layer BFL. The drain DA1, the active AC1, and the source SA1 may form the transistor TFT with a gate GT1 described later. When the display panel DP includes another transistor in addition to the transistor TFT, the another transistor may include a material different from that of the transistor TFT and/or layers or patterns of the another transistor may be disposed on a different layer from the transistor TFT. The source SA1, the active AC1, and the drain DA1 of the transistor TFT may be respective areas or patterns formed from the semiconductor pattern (or the semiconductor layer).

The first lower insulating layer 10 may be disposed on the buffer layer BFL. The first lower insulating layer 10 may cover the semiconductor pattern. The first lower insulating layer 10 may commonly overlap the pixels.

The gate GT1 may be disposed on the first lower insulating layer 10. The gate GT1 may be a portion of a metal pattern of a first conductive layer (or first metal material layer). The gate GT1 may overlap the active AC1. The gate GT1 may be used as a mask in a process of doping the semiconductor pattern within a method of providing the display panel DP.

The gate GT1 may include titanium (Ti), silver (Ag), an alloy containing silver (Ag), molybdenum (Mo), an alloy containing molybdenum (Mo), aluminum (Al), an alloy containing aluminum (Al), aluminum nitride (AlN), tungsten (W), tungsten nitride (WN), copper (Cu), indium tin oxide (ITO), indium zinc oxide (IZO), or the like, however, should not be particularly limited.

The second lower insulating layer 20 may be disposed on the first lower insulating layer 10 and may cover the gate GT1. The second lower insulating layer 20 may commonly overlap the pixels PX. Although not show in figures, an upper electrode may be disposed on the second lower insulating layer 20 to overlap the gate GT1.

The third lower insulating layer 30 may be disposed on the second lower insulating layer 20 to cover the upper electrode. The first connection electrode CNE1 disposed on the third lower insulating layer 30 may be connected to the drain DA1 of the transistor TFT via a contact hole CNT-1 defined through the first, second, and third lower insulating layers 10, 20, and 30.

The fourth lower insulating layer 40 may be disposed on the third lower insulating layer 30. The second connection electrode CNE2 may be disposed on the fourth lower insulating layer 40. The second connection electrode CNE2 may be connected to the first connection electrode CNE1 via a contact hole CNT-2 defined through the fourth lower insulating layer 40.

The fifth lower insulating layer 50 may be disposed on the fourth lower insulating layer 40 and may cover the second connection electrode CNE2.

The display element layer DP-OLED may include the pixel definition layer PDL and the light emitting element LD.

The pixel definition layer PDL may be disposed on the fifth lower insulating layer 50. The pixel definition layer PDL may cover a portion of a first electrode AE, e.g., an anode, of the light emitting element LD.

An pixel opening PDL-OP may be defined through the pixel definition layer PDL, by a solid material portion thereof, to expose a portion of the first electrode AE to outside the pixel definition layer PDL. The light emitting area LA may be defined to correspond to a portion of the first electrode AE exposed through the pixel opening PDL-OP. That is, a planar area of the exposed portion of the first electrode AE may define the light emitting area LA. The area overlapping the solid material portion of the pixel definition layer PDL may be defined as the non-light-emitting area NLA.

The light emitting element LD may include the first electrode (or the anode) AE, a light emitting layer EML, and a second electrode (or a cathode) CE. Although not shown in FIG. 3B, the light emitting element LD may further include a hole control layer disposed between the first electrode AE and the light emitting layer EML and an electron control layer disposed between the second electrode CE and the light emitting layer EML. The hole control layer may include a hole transport layer and a hole injection layer, and the electron control layer may include an electron transport layer and an electron injection layer.

The first electrode AE may be disposed on the fifth lower insulating layer 50. The first electrode AE may be a semi-transmissive electrode, a transmissive electrode, or a reflective electrode. According to an embodiment, the first electrode AE may include a reflective layer formed of (or including) Ag, Mg, Al, Pt, Pd, Au, Ni, Nd, Ir, Cr, or compounds thereof and a transparent or semi-transparent electrode layer formed on the reflective layer. The transparent or semi-transparent electrode layer may include at least one selected from indium tin oxide (ITO), indium zinc oxide (IZO), indium gallium zinc oxide (IGZO), zinc oxide (ZnO), indium oxide (In2O3), and aluminum-doped zinc oxide (AZO). For instance, the first electrode AE of the light emitting element LD may have a stack structure of ITO/Ag/ITO.

The first electrode AE may be disposed on the fifth lower insulating layer 50. The first electrode AE may be connected to the second connection electrode CNE2 via a contact hole CNT-3 defined through the fifth lower insulating layer 50.

The light emitting layer EML may be disposed on the first electrode AE. The light emitting layer EML may be disposed in an area corresponding to the pixel opening PDL-OP. That is, a material layer forming the light emitting layer EML as a pattern may be divided into portions (e.g., patterns of light emitting material), and the divided portions of the light emitting layer EML may be respectively disposed in the pixels PX, however, the present disclosure should not be limited thereto or thereby. According to an embodiment, the light emitting layer EML may be commonly formed over the plural pixels PX, such as by using an open mask.

The second electrode CE may be disposed on the light emitting layer EML. The second electrode CE may have an integral shape and may be commonly disposed over the pixels PX.

The encapsulation layer TFL may be disposed on the display element layer DP-OLED. The encapsulation layer TFL may include a first inorganic layer 141, an organic layer 142 disposed on the first inorganic layer 141, and a second inorganic layer 143 disposed on the organic layer 142, however, should not be limited thereto or thereby. According to an embodiment, the encapsulation layer TFL may further include organic layers and inorganic layers.

The first inorganic layer 141 and the second inorganic layer 143 may include a silicon nitride layer, a silicon oxynitride layer, a silicon oxide layer, a titanium oxide layer, or an aluminum oxide layer. The organic layer 142 may include an acrylic-based organic layer.

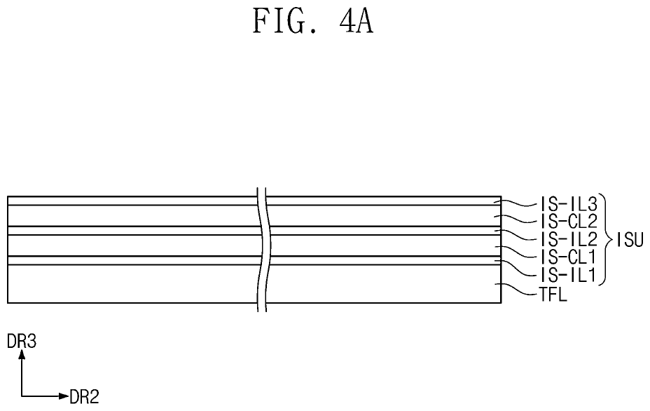

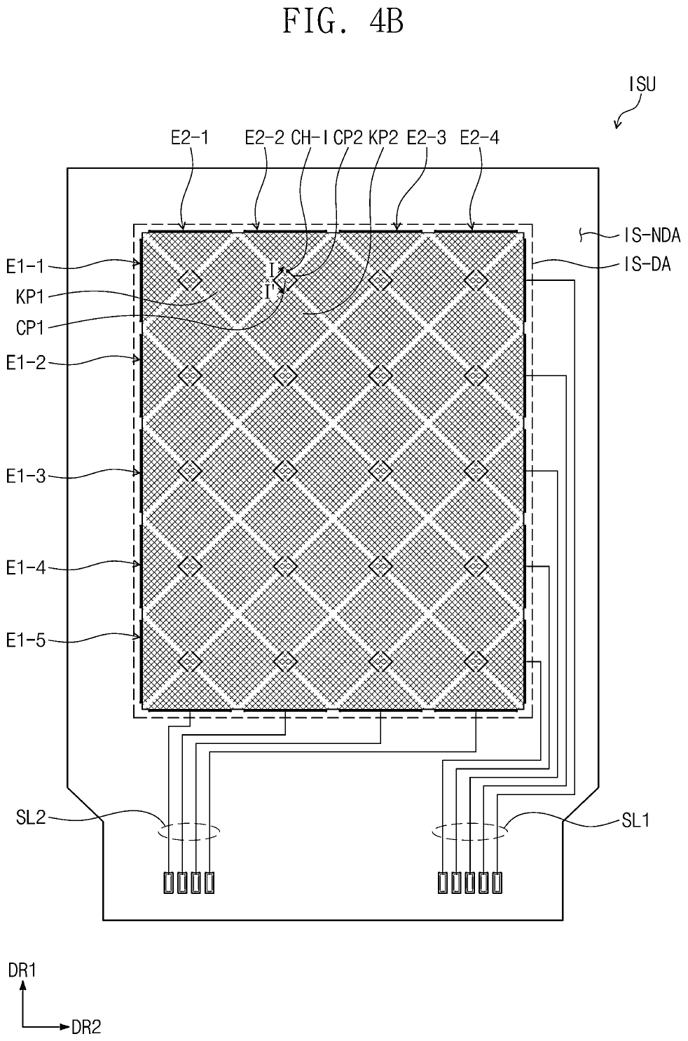

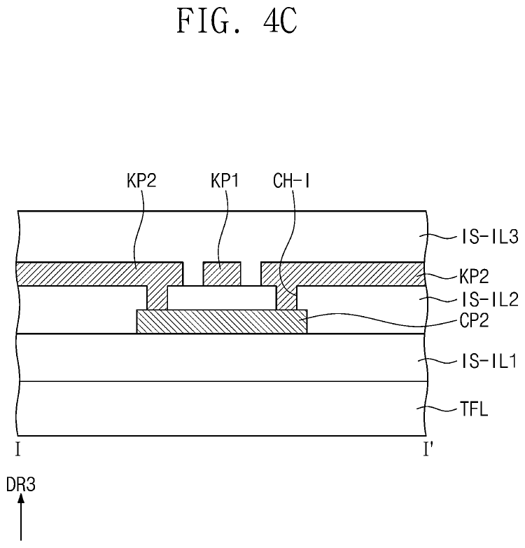

FIG. 4A is a cross-sectional view of the input sensing unit ISU according to an embodiment of the present disclosure.

The input sensing unit ISU may include a first upper insulating layer IS-IL1, a first sensing conductive layer IS-CL1 disposed on the first upper insulating layer IS-IL1, a second upper insulating layer IS-IL2 disposed on the first sensing conductive layer IS-CL1, a second sensing conductive layer IS-CL2 disposed on the second upper insulating layer IS-IL2, and a third upper insulating layer IS-IL3 disposed on the second sensing conductive layer IS-CL2. The first upper insulating layer IS-IL1 may be disposed directly on the encapsulation layer TFL.

However, the first upper insulating layer IS-IL1 and/or the third upper insulating layer IS-IL3 may be omitted. When the first upper insulating layer IS-IL1 is omitted, the first sensing conductive layer IS-CL1 may be disposed directly on the encapsulation layer TFL. The third upper insulating layer IS-IL3 may be replaced with an adhesive layer or an insulating layer of the anti-reflective member of the input sensing unit ISU.

Each of the first, second, and third upper insulating layers IS-IL1, IS-IL2, and IS-IL3 may include an inorganic layer or an organic layer. The inorganic layer may include silicon oxide, silicon nitride, or silicon oxynitride. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

In the present embodiment, at least one of the first, second, and third upper insulating layers IS-IL1, IS-IL2, and IS-IL3 may be an organic layer. For instance, the third upper insulating layer IS-IL3 may include an organic layer.

FIG. 4A shows each of the first sensing conductive layer IS-CL1 and the second sensing conductive layer IS-CL2 as a single layer which entirely overlaps the display panel DP (e.g., overlaps an entirety of the display panel DP) to schematically represent the stacked structure, however, the present disclosure should not be limited thereto or thereby. According to an embodiment, each of the first sensing conductive layer IS-CL1 and the second sensing conductive layer IS-CL2 may be patterned, such as to define discrete patterns separated from each other along the encapsulation layer TFL.

FIG. 4B is a plan view of the input sensing unit ISU according to an embodiment of the present disclosure. FIG. 4C is a cross-sectional view of a portion of the display device DD taken along line I-I′ of FIG. 4B.

Referring to FIG. 4B, the input sensing unit ISU may include a sensing area IS-DA and a non-sensing area IS-NDA which is adjacent to the sensing area IS-DA. The sensing area IS-DA and the non-sensing area IS-NDA may correspond to the display area DP-DA (refer to FIG. 2) and the non-display area DP-NDA (refer to FIG. 2) shown in FIG. 2, respectively.

Referring to FIG. 4B, the input sensing unit ISU may include first electrodes E1-1 to E1-5 as first sensing electrodes, second electrodes E2-1 to E2-4 as second sensing electrodes, first signal lines SL1 as first sensing signal lines, and second signal lines SL2 as second sensing signal lines.

The first electrodes E1-1 to E1-5 and the second electrodes E2-1 to E2-4 may be disposed in the sensing area IS-DA and may be insulated from each other while crossing each other in the plan view.

The first signal lines SL1 and the second signal lines SL2 may be disposed in the non-sensing area IS-NDA. The first signal lines SL1 may be electrically connected to the first electrodes E1-1 to E1-5, respectively, and the second signal lines SL2 may be electrically connected to the second electrodes E2-1 to E2-4, respectively.

The first electrodes E1-1 to E1-5, the second electrodes E2-1 to E2-4, the first signal lines SL1, and the second signal lines SL2 may be portions of the first sensing conductive layer IS-CL1 or the second sensing conductive layer IS-CL2.

Each of the first electrodes E1-1 to E1-5 and the second electrodes E2-1 to E2-4 may include a plurality of conductive lines intersecting each other. The conductive lines may define a plurality of openings therebetween, and each of the first electrodes E1-1 to E1-5 and the second electrodes E2-1 to E2-4 may have a mesh shape defined by the openings and the solid material portions of the conductive lines intersecting each other. Each of the openings may be defined to correspond to the pixel opening PDL-OP of the pixel definition layer PDL shown in FIG. 3B.

The first electrodes E1-1 to E1-5 may include sensing portions KP1 as first sensing patterns and intermediate portions CP1 which extend from the sensing portions KP1 and provided integrally with the sensing portions KP1. That is, the sensing portions KP1 and the intermediate portions CP1 may be patterned through the same process and may be integrally formed with each other such as to be patterns of a same material layer, but for the convenience of explanation, they will be explained separately.

The second electrodes E2-1 to E2-4 may include sensing patterns KP2 as second sensing patterns and bridge patterns (or connection patterns) CP2.

Referring to FIGS. 4B and 4C, two sensing patterns KP2 adjacent to each other may be connected to the bridge pattern CP2, via a contact hole CH-I defined through the second upper insulating layer IS-IL2. The bridge pattern CP2 may be exposed to outside the second upper insulating layer IS-IL2 by the contact hole CH-I.

One of the first signal lines SL1 and the second signal lines SL2 may transmit a transmission signal to sense an external input from an external circuit, and the other of the first signal lines SL1 and the second signal lines SL2 may transmit a variation in capacitance between the first sensing electrodes E1-1 to E1-5 and the second sensing electrodes E2-1 to E2-4, to the external circuit as a reception signal.

The first signal lines SL1 and the second signal lines SL2 may have a multi-layer structure, and a first-layer line and a second-layer line may be connected to each other via the contact hole CH-I (refer to FIG. 4C) defined through the second upper insulating layer IS-IL2.

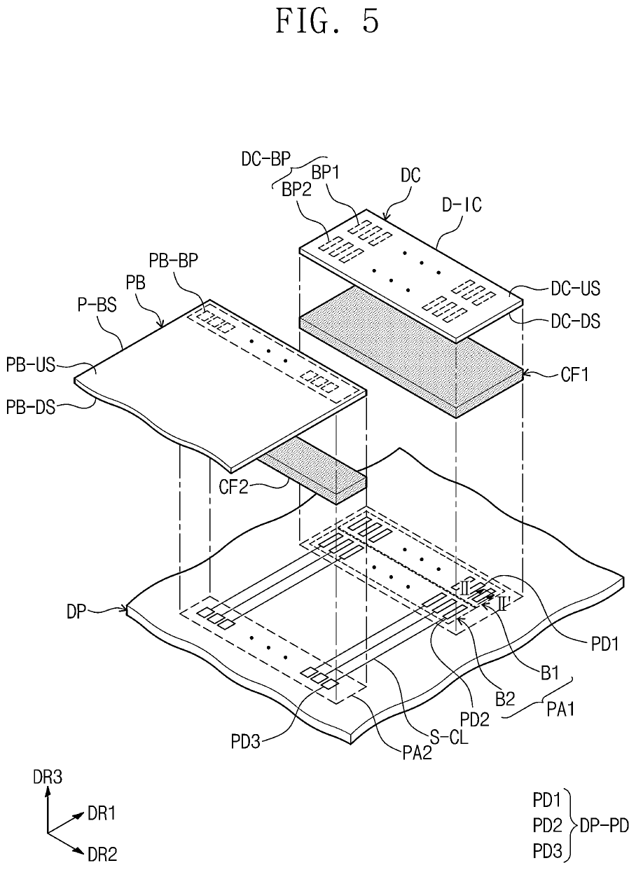

FIG. 5 is an enlarged exploded perspective view of a pad area of the display device DD according to an embodiment of the present disclosure. As an example, the driving chip DC and the circuit board PB are shown as being separated from the display panel DP in FIG. 5. Since the arrangement and connection relationships between the first pad area PA1 and the second pad area PA2 are described above with reference to FIG. 3A, redundant description will be omitted.

Referring to FIG. 5, the driving chip DC may be bonded to the display panel DP at the first pad area PA1, by a first adhesive layer CF1. The circuit board PB may be bonded to the display panel DP at the second pad area PA2, by a second adhesive layer CF2.

In the present embodiment, the first adhesive layer CF1 and the second adhesive layer CF2 may include a non-conductive film (NCF) instead of an anisotropic conductive film (ACF). Accordingly, the first adhesive layer CF1 and the second adhesive layer CF2 as a non-conductive adhesive may include a synthetic resin with an adhesive property and may not include a conductive member such as conductive balls. Therefore, as will be described later, a defect such as an electrical short circuit occurring when the first adhesive layer CF1 and the second adhesive layer CF2 include conductive balls in the first and second pad areas PA1 and PA2, respectively, may be prevented.

The driving chip DC may include a driving integrated circuit D-IC and driving bumps DC-BP which are provided in the driving chip DC.

The driving integrated circuit D-IC may include an upper surface DC-US and a lower surface DC-DS which is opposite to the upper surface DC-US. The lower surface DC-DS of the driving integrated circuit D-IC may face the first and second pads PD1 and PD2.

The driving bumps DC-BP may be disposed on the lower surface DC-DS of the driving integrated circuit D-IC. The driving bumps DC-BP may include first bumps BP1 at which the driving chip DC is electrically connected to the first pads PD1, respectively, and second bumps BP2 at which the driving chip DC is electrically connected to the second pads PD2, respectively.

The first bumps BP1 may be arranged in the second direction DR2, and the second bumps BP2 may be spaced apart from the first bumps BP1 in the first direction DR1 and may be arranged in the second direction DR2. FIG. 5 shows a structure in which each of the first bumps BP1 and the second bumps BP2 are arranged in a single row along the second direction DR2 as a representative example, however, the present disclosure should not be limited thereto or thereby. According to an embodiment, each of the first bumps BP1 and the second bumps BP2 may be arranged in two or more rows.

The driving chip DC may receive first signals via the second pads PD2 as output pads of the display panel DP and the second bumps BP2 as input pads of the driving chip DC. The driving chip DC may apply second signals generated based on the first signals to the first pads PD1 as input pads of the display panel DO via the first bumps BP1 as output pads of the driving chip DC. As an example, the driving chip DC may include a data driving circuit and may generate the second signals based on the first signals using the data driving circuit.

The first signal may be an image signal which is a digital signal provided from the outside, and the second signal may be a data signal which is an analog signal. The driving chip DC may generate an analog voltage corresponding to a grayscale value of the image signal. The data signal may be applied to the light emitting element LD (refer to FIG. 3B) of the pixel PX (refer to FIG. 3A) via the data line DL (refer to FIG. 3A) shown in FIG. 3.

Although not shown in FIG. 5, the first bumps BP1 and the second bumps BP2 may protrude from the lower surface DC-DS of the driving integrated circuit D-IC and may be exposed to the outside of the driving chip DC. When the first adhesive layer CF1 is cured, the first pads PD1 may be attached to and fixed to the first bumps BP1, and the second pads PD2 may be attached to and fixed to the second bumps BP2, such that the driving chip DC and the display panel DP are electrically connected to each other. That is, the display pads may be physically and electrically connected the driving chip bumps, such that the driving chip DC and the display panel DP are electrically connected to each other.

The circuit board PB may include a base layer P-BS and the substrate bumps PB-BP which are provided in the circuit board PB. The circuit board PB may include an upper surface PB-US and a lower surface PB-DS which is opposite to the upper surface PB-US, and the lower surface PB-DS of the circuit board PB may face the third pads PD3.

The substrate bumps PB-BP may be disposed on the lower surface PB-DS of the base layer P-BS. The substrate bumps PB-BP may be electrically connected to the display panel DP at the third pads PD3, respectively.

The substrate bumps PB-BP may be arranged in the second direction DR2. FIG. 5 shows a structure in which the substrate bumps PB-BP are arranged in a single row along the second direction DR2 as a representative example, however, the present disclosure should not be limited thereto or thereby. According to an embodiment, the substrate bumps PB-BP may be arranged in two or more rows.

The circuit board PB may provide image signals, driving voltages, and control signals to the driving chip DC.

Although not shown in figures, the substrate bumps PB-BP may protrude from the lower surface PB-DS of the base layer P-BS and may be exposed to the outside of the circuit board PB. When the second adhesive layer CF2 is cured, the third pads PD3 may be (physically and electrically) attached to and fixed to the substrate bumps PB-BP, such that the circuit board PB and the display panel DP are electrically connected to each other.

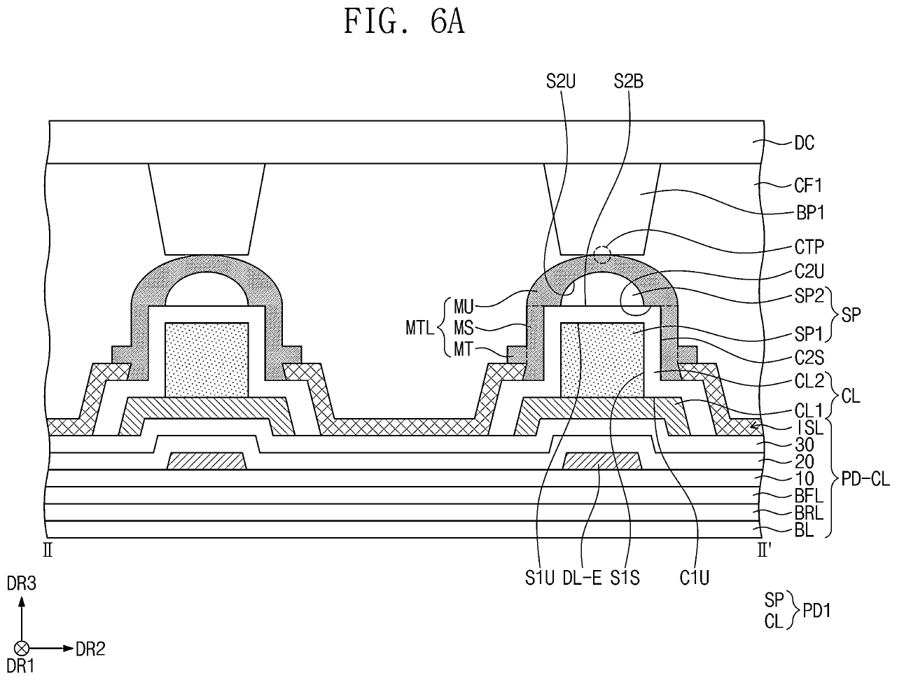

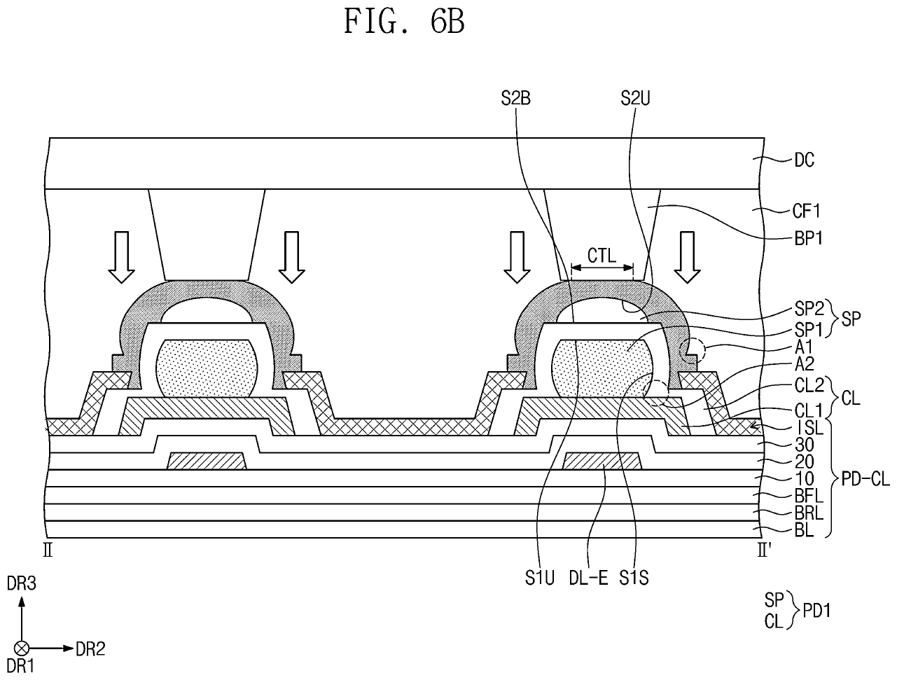

FIGS. 6A and 6B are cross-sectional views of a portion of the display device DD taken along line II-II′ of FIG. 5.

Hereinafter, a bonding structure between the first pad PD1 of the display panel DP and the first bump BP1 of the driving chip DC each disposed in the first area B1 of the pad area (refer to FIG. 5) will be described with reference to FIGS. 6A and 6B.

FIG. 6A shows a structure in which the first pad PD1 is bonded (e.g., electrically and physically) to the first bump BP1 in the first area B1, to form a contact point CTP. The contact point CTP may be defined by a physical interface of a respective display pad with a respective driving chip bump (or circuit board bump). The contact point CTP may be a point-contact having a minimal area of contact between elements. FIG. 6B shows a structure in which the driving chip DC and the first bump BP1 of FIG. 6A are moved or pressed towards each other to form a contact surface CTL. The contact surface may be defined by the physical interface of the respective display pad with the respective driving chip bump (or circuit board bump). The contact surface CTL may be more than a point-contact such as to have a planar area which is greater than a planar area of the contact point CTP.

FIGS. 6A and 6B show the first pad PD1 as a representative pad and the first bump BP1 as a representative bump. Descriptions on the contact between the first pad PD1 and the first bump BP1 with reference to FIGS. 6A and 6B may also be applied to a contact between the second pad PD2 and the second bump BP2 in the second area B2 (refer to FIG. 5) and a contact between the third pad PD3 and the substrate bump PB-BP in the second pad area PA2. As used herein, the driving chip DC and the circuit board PB may be considered an electrical component which is electrically connected to the non-display area DP-NDA at the display pad (e.g., a pad among the signal pads DP-PD).

FIGS. 6A and 6B show an end portion DL-E of a signal line such as the data line DL (refer to FIG. 3A) as a representative example of the signal lines SGL (refer to FIG. 3A). Descriptions on the signal line SGL (refer to FIG. 3A) with reference to FIGS. 6A and 6B may also be applied to other signal lines SGL in addition to the data line DL. The end portion DL-E may correspond to a respective first pad PD1.

Referring to FIG. 6A, the display panel DP may include an insulating layer PD-CL, the end portion DL-E of the data line DL (refer to FIG. 3A), the first pad PD1, a metal layer MTL, the first bump BP1, the first adhesive layer CF1, and the driving chip DC in the first area B1 (refer to FIG. 5).

The insulating layer PD-CL may include plural layers such as the base layer BL, the barrier layer BRL, the first lower insulating layer 10, the second lower insulating layer 20, the third lower insulating layer 30, and an upper insulating layer ISL, which are sequentially stacked in the third direction DR3. In this embodiment, the insulating layer PD-CL may include the base layer BL, the barrier layer BRL, the buffer layer BFL, the first lower insulating layer 10, the second lower insulating layer 20, the third lower insulating layer 30, and an upper insulating layer ISL, which are sequentially stacked in the third direction DR3.

The barrier layer BRL, the buffer layer BFL, and the insulating layers 10 to shown in FIGS. 6A and 6B may be formed through the same process as the barrier layer BRL, the buffer layer BFL, and the insulating layers 10 to 30 of the display area DP-DA shown in FIG. 3B. That is, the stack structure of the base layer BL, the barrier layer BRL, the buffer layer BFL, and the insulating layers 10 to 30 shown in FIGS. 6A and 6B may be changed depending on the stack structure of the circuit element layer DP-CL (refer to FIG. 3B).

The end portion DL-E of the data line DL (refer to FIG. 3A) may correspond to an extended portion of the data line DL (refer to FIG. 3A), which is disposed in the pad areas PA1 and PA2. The end portion DL-E may be disposed on the first lower insulating layer 10 and may be covered by the second lower insulating layer 20.

In the present embodiment, the end portion DL-E may be formed through the same process as the gate GT1 (refer to FIG. 3B). Accordingly, the end portion DL-E may be disposed on the same layer as and may include the same material as the gate GT1 (refer to FIG. 3B), however, the present disclosure should not be limited thereto or thereby. As an example, the end portion DL-E may be formed through the same process as the first connection electrode CNE1 (refer to FIG. 3B) or the second connection electrode CNE2 (refer to FIG. 3B) or may be formed through the same process as the upper electrode described with reference to FIG. 3B. That is, the end portion DL-E which is in the non-display area DP-NDA, is connected to the display area DP-DA

The first pad PD1 may be disposed on the third lower insulating layer 30. The first pad PD1 may include insulating patterns SP and conductive patterns CL. The insulating patterns SP may include the first pattern SP1 as a first insulating pattern and the second pattern SP2 as a second insulating pattern, and the conductive patterns CL may include a lower conductive pattern CL1 and an upper conductive pattern CL2.

The lower conductive pattern CL1 may be disposed on the insulating layers PD-CL. As an example, the lower conductive pattern CL1 may be disposed on the third lower insulating layer 30. Although not shown in figures, the lower conductive pattern CL1 may be in contact (e.g., physically and/or electrically) with the end portion DL-E via a contact hole (not shown) defined through the second and third lower insulating layers 20 to 30. Accordingly, the lower conductive pattern CL1 may be electrically connected to the end portion DL-E.

The first pattern SP1 may be disposed on the lower conductive pattern CL1. The first pattern SP1 may have a quadrangular shape when viewed in the cross-section, however, the cross-sectional shape of the first pattern SP1 should not be limited to the quadrangular shape.

Referring to FIG. 6A, the first pattern SP1 may be in contact with the first conductive pattern CL1, however, the present disclosure should not be limited thereto or thereby. According to an embodiment, an insulating layer may be further disposed between the first pattern SP1 and the first conductive pattern CL1. In this case, the first pattern SP1 may not be in contact with the first conductive pattern CL1. An outer surface of the first conductive pattern CL1 may be exposed outside of the first pattern SP1, since the first conductive pattern CL1 extends further than an outer surface (or sidewall) of the first pattern SP1.

The upper conductive pattern CL2 may be disposed on the lower conductive pattern CL1 and may overlap at least a portion of the first pattern SP1. In the present embodiment, the upper conductive pattern CL2 may be disposed on the first pattern SP1. The upper conductive pattern CL2 may be at least partially disposed between the first pattern SP1 and the second pattern SP2. The upper conductive pattern CL2 may cover an upper surface S1U of the first pattern SP1 and side surfaces SIS of the first pattern SP1 and may cover at least a portion of an upper surface C1U of the lower conductive pattern CL1.

The second pattern SP2 may be disposed on the first pattern SP1. In the present embodiment, the second pattern SP2 may be disposed on the upper conductive pattern CL2.

An upper surface S2U of the second pattern SP2 may have a predetermined curvature. The second pattern SP2 may have a width in a planar direction along the insulating layer PD-CL, which decreases as a distance from the base layer BL increases. That is, in the present embodiment, the width of the second pattern SP2 in the second direction DR2 (and/or the first direction DR1) may decrease as the thickness-direction distance from the base layer BL increases. In an embodiment, the second pattern may include an upper surface which is convexly curved in a direction away from the base layer BL, and a width in a direction along the base layer BL, the width decreasing as a distance from the base layer BL increases.

The second pattern SP2 may have a dome shape whose curved surface faces the third direction DR3. FIG. 6A shows the structure in which the second pattern SP2 has a semi-circular cross-sectional shape with the curved surface facing the third direction DR3 as a representative example, however, the cross-sectional shape of the second pattern SP2 should not be limited thereto or thereby.

A lower surface S2B of the second pattern SP2 may cover at least a portion of the upper surface C2U of the upper conductive pattern CL2. FIG. 6A shows the structure in which a width in the second direction DR2 of the lower surface S2B of the second pattern SP2 when viewed in the cross-section is smaller than a width in the second direction DR2 of the upper surface C2U of the upper conductive pattern CL2 when viewed in the cross-section, and the lower surface S2B of the second pattern SP2 covers the portion of the upper surface C2U of the upper conductive pattern CL2.

The metal layer MTL may include a metal layer upper portion MU extended along the upper surface S2U and covering the second pattern SP2, and a metal layer side portion MS disposed adjacent to the upper conductive pattern CL2 in the second direction DR2 and extended along an outer surface of the upper conductive pattern CL2. In addition, the metal layer MTL may further include a metal layer tip portion MT disposed on the upper insulating layer ISL and protruded in the planar direction in which the first pads PD1 are arranged. That is, in the present embodiment, the metal layer tip portion MT as a protruding portion of the metal layer MTL may protrude in the second direction DR2. According to an embodiment, the metal layer side portion MS and the metal layer tip portion MT may be provided in plural.

The metal layer upper portion MU, the metal layer side portion MS, and the metal layer tip portion MT are defined, for the convenience of explanation, to respectively refer to distinct portions of the metal layer MTL by virtual boundaries indicated by dotted lines in FIG. 6A. However, the metal layer MTL may have a continuous shape defined by the various aforementioned portions.

The metal layer MTL may be disposed on the first pad PD1 to at least partially cover the upper surface S2U of the second pattern SP2 and a side surface C2S of the upper conductive pattern CL2. Referring to FIG. 6A, the metal layer upper portion MU may cover the upper surface S2U of the second pattern SP2, and the metal layer side portion MS may be disposed on the side surface C2S of the upper conductive pattern CL2 to cover at least a portion of the side surface C2S of the upper conductive pattern CL2.

The metal layer MTL may cover at least a portion of the upper surface C2U of the upper conductive pattern CL2. FIG. 6A shows a structure in which the metal layer upper portion MU covers both ends in the second direction DR2 of the upper surface C2U of the upper conductive pattern CL2 as a representative example.

The metal layer side portion MS may be in contact with at least a portion of the upper insulating layer ISL. FIG. 6A shows a structure in which a lower end of the metal layer side portion MS is in contact with the upper insulating layer ISL as a representative example.

The upper insulating layer ISL may be disposed to at least partially cover the third lower insulating layer 30 and the upper conductive pattern CL2.

The upper insulating layer ISL may be in contact with at least a portion of the metal layer MTL. FIG. 6A shows a structure in which the upper insulating layer ISL is in contact with a side surface of the metal layer side portion MS and a lower surface of the metal layer tip portion MT as a representative example. However, a position where the upper insulating layer ISL is in contact with the metal layer side portion MS should not be limited thereto or thereby.

The upper insulating layer ISL may include the first upper insulating layer IS-IL1 (refer to FIG. 4B) and the second upper insulating layer IS-IL2 (refer to FIG. 4B), but should not be limited thereto or thereby. That is, the upper insulating layer ISL in the non-display area DP-NDA may be extended portions of the upper insulating layers within the input sensing unit ISU which correspond to the display area DP-DA.

The driving chip DC and the first bumps BP1 which are arranged spaced apart from each other under the driving chip DC may be disposed on the first pad PD1. As the driving chip DC and the first bumps BP1 move toward each other (indicated by the downward arrows in FIG. 6B), an interface between each of the first bumps BP1 and the respective pads may be increased at the metal layer upper portion MU of the respective pads.

The second pattern SP2 and the metal layer upper portion MU which covers the second pattern SP2 may have a dome shape on the upper conductive pattern CL2. That is, the cross-sectional shape of the metal layer upper portion MU may correspond to the cross-sectional shape of the second pattern SP2. Accordingly, the cross-section of each of the second pattern SP2 and the metal layer upper portion MU may have a size which decreases in a direction away from the insulating layer PD-CL, that is, in the third direction DR3.

Accordingly, in an embodiment, when the first bumps BP1 descend and are in contact with the metal layer upper portion MU overlapping therewith, a point contact as an initial may occur. In the present embodiment, the point contact may be defined as a contact where each of the first bumps BP1 and the metal layer upper portion MU meet in the form of a point or an area with a very small surface. FIG. 6A shows the contact point CTP formed at the contact portion between the metal layer upper portion MU and the first bump BP1.

As the metal layer upper portion MU is in point contact with the first bump BP1, a force applied to the metal layer upper portion MU by the first bump BP1 may be concentrated on the contact point CTP. That is, the force applied to the metal layer upper portion MU by the first bump BP1 may be concentrated in a small planar area at the contact point CTP. A pressure applied to the metal layer MTL by the first bump BP1 may increase, and the metal layer upper portion MU may be deformed in a direction of the pressure. As an example, the metal layer upper portion MU may be tensioned. That is, the metal layer upper portion MU may be tensioned due to the pressure applied to the metal layer MTL by the first bump BP1 in a direction toward the base layer BL (e.g., along the thickness direction).

In the present disclosure, the pressure applied to the metal layer MTL by the first bump BP1 in a bonding process may be referred to as a bonding pressure.

The first pattern SP1 may include a first photosensitive material, and the second pattern SP2 may include a second photosensitive material different from the first photosensitive material.

The first photosensitive material may be a polymer with a negative photosensitivity, and the second photosensitive material may be a polymer with a positive photosensitivity. Accordingly, it may be easy to manufacture (or provide) the first pattern SP1 and the second pattern SP2 into different discrete pattern shapes in the photoresist process. As an example, it may be easy to etch the second pattern SP2 in the dome shape.

In addition, since the polymer has a modulus (e.g., an elastic modulus) smaller than that of a metal material, the first pattern SP1 and the second pattern SP2 may absorb the bonding pressure applied to the metal layer MTL in the bonding process. As such, the first pattern SP1 and/or the second pattern SP2 may be referred to as an elastic pattern, an impact-absorbing pattern, a bonding pressure-absorbing pattern, a compressible pattern or the like. Accordingly, the occurrence of cracks of layers of the first pad PD1 due to the bonding pressure may be prevented.

However, the present disclosure should not be limited thereto or thereby. As an example, the first photosensitive material may be a polymer with a negative photosensitivity, and the second photosensitive material may be a metal material with a positive photosensitivity. Accordingly, the second pattern SP2 may absorb the bonding pressure and may also have a relatively high modulus, and thus, a structural stability of the first pad PD1 may be improved.

The lower conductive pattern CL1 and the upper conductive pattern CL2 may be formed through the same process as other conductive patterns described with reference to FIGS. 3B and 4A. As an example, the lower conductive pattern CL1 and the upper conductive pattern CL2 in the non-display area DP-NDA may be formed through the same process as the first connection electrode CNE1 and the second connection electrode CNE2 of the display area DP-DA, respectively. Accordingly, the lower conductive pattern CL1 and the upper conductive pattern CL2 may be disposed on the same layer as and may include the same material as the first connection electrode CNE1 and the second connection electrode CNE2, respectively, however, the present disclosure should not be limited thereto or thereby. According to an embodiment, the lower conductive pattern CL1 and the upper conductive pattern CL2 may be formed through the same process as or formed through different process from a conductive pattern included in other conductive layers.

The lower conductive pattern CL1 may include a metal material and may have a single-layer or multi-layer structure. As an example, the lower conductive pattern CL1 may include a first lower pattern layer containing titanium (Ti), a second lower pattern layer disposed on the first lower pattern layer and containing aluminum (Al), and a third lower pattern layer disposed on the second lower pattern layer and containing titanium (Ti).

The upper conductive pattern CL2 may include a metal material and may have a single-layer or multi-layer structure. As an example, the upper conductive pattern CL2 may include a first upper pattern layer containing titanium (Ti), a second upper pattern layer disposed on the first upper pattern layer and containing aluminum (Al), and a third upper pattern layer disposed on the second upper pattern layer and containing titanium (Ti).

The metal layer MTL may be formed through the same process as other conductive patterns described with reference to FIGS. 3B and 4A. As an example, the metal layer MTL in the non-display area DP-NDA may be formed through the same process as the first sensing conductive layer IS-CL1 (refer to FIG. 4A) or the second sensing conductive layer IS-CL2 (refer to FIG. 4A) corresponding to the display area DP-DA, however, the present disclosure should not be limited thereto or thereby. According to an embodiment, the metal layer MTL may be formed through the same process as or formed through different process from a conductive pattern included in other conductive layers.

The metal layer MTL may include a metal material and may have a single-layer or multi-layer structure. As an example, the metal layer MTL may include a first metal layer containing titanium (Ti), a second metal layer disposed on the first metal layer and containing aluminum (Al), and a third metal layer disposed on the second metal layer and containing titanium (Ti). That is, within a respective display pad, each of the upper conductive pattern CL2 and the lower conductive pattern CL1 may include a first metal layer including titanium, a second metal layer on the first metal layer and including aluminum, and a third metal layer on the second metal layer and including titanium. The above metal layers may be respectively arranged in a direction normal to an underlying surface along which a metal layer is disposed.

FIG. 6B shows the state in which the driving chip DC and the first bump BP1 descend together with each other, and a structural deformation occurs in portions of the first pad PD1 and the metal layer MTL. However, the deformed shape of the portions of the first pad PD1 and the metal layer MTL may vary depending on the descent level of the driving chip DC and the first bump BP1.

Referring to FIG. 6B, as the metal layer upper portion MU is deformed, the size of the contact portion (or contact area) between the first bump BP1 and the metal layer upper portion MU may become greater than the contact point CTP (refer to FIG. 6A). FIG. 6B shows a structure in which the contact portion between the first bump BP1 and the metal layer upper portion MU becomes the contact surface CTL (refer to FIG. 6B) as a representative example. Accordingly, the force applied to the metal layer upper portion MU by the first bump BP1 may be distributed over a wide planar area after the metal layer upper portion MU is sufficiently tensioned, and thus, the bonding pressure may be reduced.

The bonding pressure may be transferred to the metal layer side portions MS through the metal layer upper portion MU. Accordingly, the metal layer side portion MS may be partially bent or deformed from a vertical direction to be recessed in a direction toward the first pattern SP1. Therefore, a first anchor portion A1 may be formed in the metal layer side portion MS by recessing a portion of the metal layer side portion MS.

Referring to FIG. 6B, the first anchor portion A1 may be formed between the metal layer side portion MS and the metal layer tip portion MT, however, the position of the first anchor portion A1 should not be limited thereto or thereby. The recess provided by the first anchor portion A1 (FIG. 6B) may be disposed under or further inside relative to an outer sidewall of the metal layer side portion MS, whereas a step between the metal layer side portion MS and the metal layer tip portion MT (FIG. 6A) which corresponds to the first anchor portion A1 coincides with the outer sidewall of the metal layer side portion MS.

As the first anchor portion A1 is formed, the contact state between the metal layer side portion MS and the upper insulating layer ISL may be maintained, and the bonding pressure may be distributed. Accordingly, the risk of cracks occurring in the first pad PD1 during the bonding process may be reduced.

The bonding pressure may be transferred to the first pattern SP1 through the metal layer MTL and the second pattern SP2. As the first pattern SP1 is compressed downward while being in contact with the lower conductive pattern CL1, the side surface SIS of the first pattern SP1 may be provided as an outwardly curved surface. Accordingly, a second anchor portion A2 may be formed at at least a portion of the side surface SIS of the first pattern SP1. Referring to FIG. 6B, the second anchor portion A2 may be formed under the side surface SIS of the first pattern SP1, however, the position of the second anchor portion A2 should not be limited thereto or thereby. The recess provided by the second anchor portion A2 (FIG. 6B) may be disposed under or further inside relative to an outer sidewall of the first pattern SP1, whereas a step between the first pattern SP1 and the lower conductive pattern CL1 (FIG. 6A) which corresponds to the second anchor portion A2 coincides with the outer sidewall of the first pattern SP1.

A separation space may be defined between the driving chip DC and the base layer BL, and the separation space may be filled with a non-conductive adhesive material. In an embodiment, a gap (e.g., the separation space) is defined between the driving chip DC and the display pad, where the non-conductive adhesive material fills the gap. Since there is no need to align conductive balls, the non-conductive adhesive material may have a relatively low viscosity compared to the anisotropic conductive film. Referring to FIG. 6A, the non-conductive adhesive material may be represented by the first adhesive layer CF1 which is between the driving chip DC and the stacked structure to which the driving chip DC is in contact.

As the first bump BP1 descends, the first bump BP1 may be in contact with the contact portion of the upper conductive pattern CL2 after penetrating the first adhesive layer CF1. That is, movement of the first bump BP1 and the stacked structure (layers MTL through BL, for example) in a direction towards each other, may include the first bump BP1 penetrating the first adhesive layer CF1.

According to an embodiment, the first bump BP1, the metal layer MTL, the upper conductive pattern CL2, the lower conductive pattern CL1, and the end portion DL-E may be sequentially in contact (e.g., physically and/or electrically) with one another along a signal transmission path. Accordingly, the first bump BP1, the metal layer MTL, the upper conductive pattern CL2, the lower conductive pattern CL1, and the end portion DL-E may be electrically connected to each other. Therefore, the driving signal provided from the driving chip DC (e.g., at the first bump BP1) may be transferred along the signal transmission path (e.g., by elements MTL, CL2, CL1 and DL-E) to the light emitting element LD electrically connected to the signal transmission path at the end portion DL-E (refer to FIG. 3B).

The first pad PD1 and the first bump BP1 may be directly bonded to each other without being connected to each other through the anisotropic conductive film which requires the conductive balls. Thus, even though the display panel DP has a high-resolution and includes multiple pixels PX, a short circuit phenomenon due to the conductive balls may be prevented. Accordingly, the reliability of the electronic device ED may be improved.

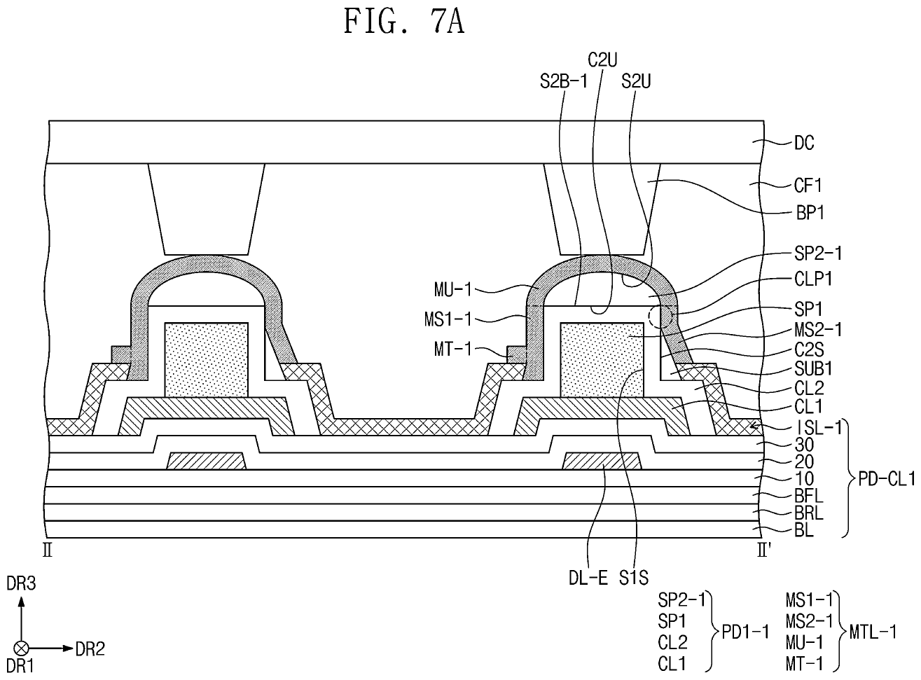

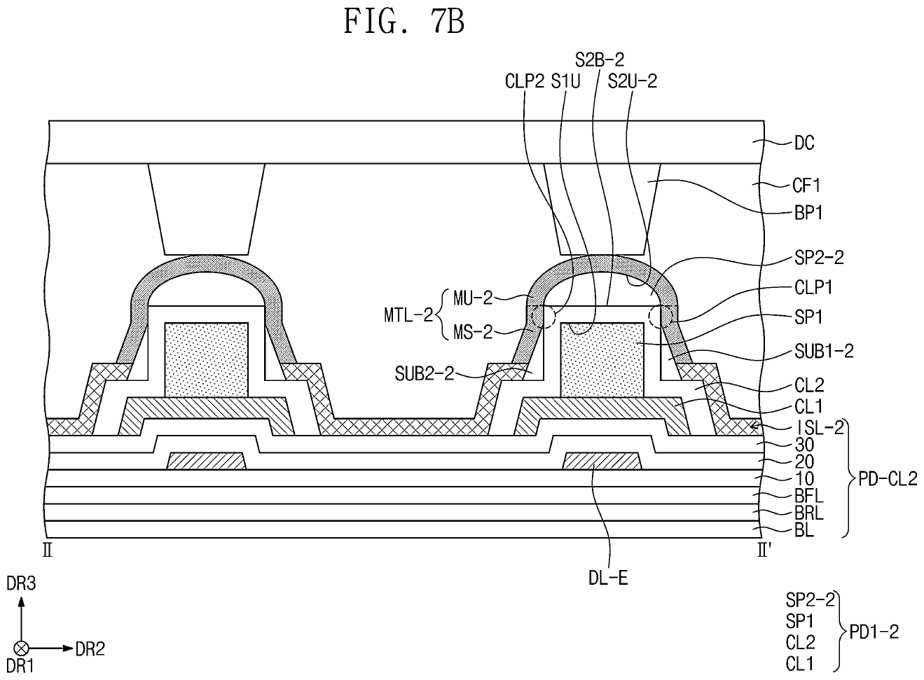

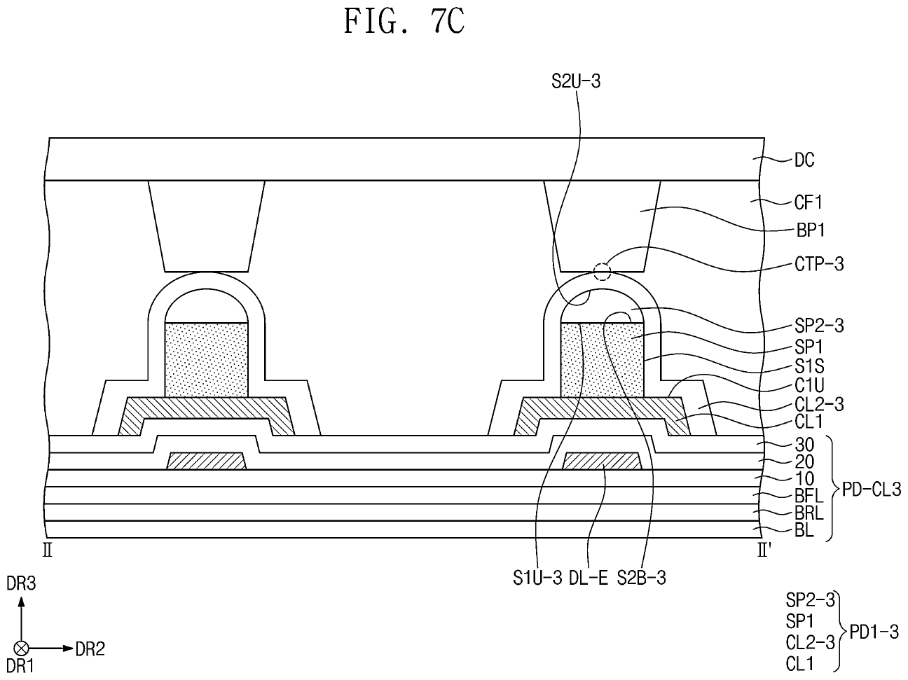

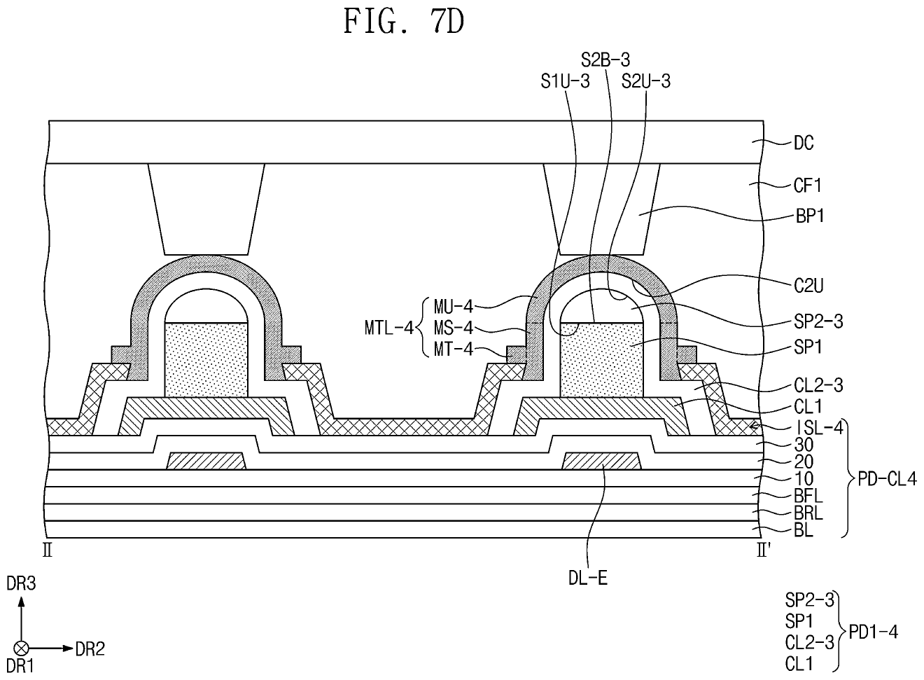

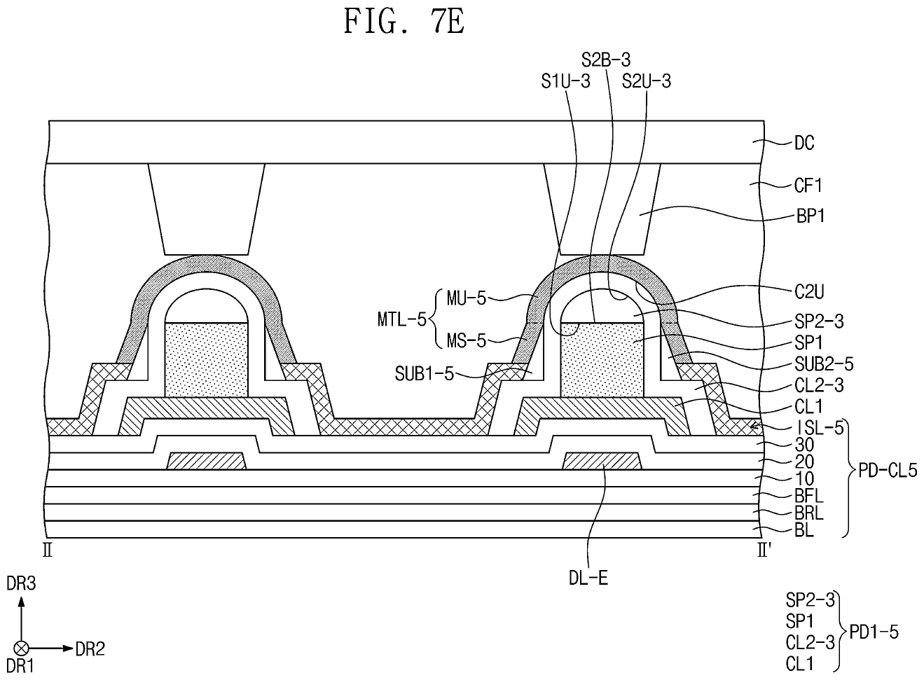

FIGS. 7A to 7E are cross-sectional views of a portion of a display device taken along line II-II′ of FIG. 5.

FIGS. 7A to 7E show a first pad PD1 as a representative example of a pad and a first bump BP1 as a representative example of a bump. Descriptions on a contact between the first pad PD1 and the first bump BP1 with reference to FIGS. 7A to 7E may be applied to a contact between a second pad PD2 and a second bump BP2 in a second area B2 (refer to FIG. 5) and a contact between a third pad PD3 and a substrate bump PB-BP in a second pad area PA2 (refer to FIG. 5). Thus, redundant description will be omitted.

FIGS. 7A to 7E show an end portion DL-E of a data line DL (refer to FIG. 3A) as an example of signal lines SGL (refer to FIG. 3A). Descriptions on the signal line SGL (refer to FIG. 3A) with reference to FIGS. 7A to 7E may be applied to other signal lines SGL in addition to the data line DL.

In FIGS. 7A to 7E, the same/similar reference numerals denote the same/similar elements in FIGS. 6A and 6B, and thus, detailed descriptions of the same elements will be omitted and descriptions will be focused on different features.

Referring to FIG. 7A, a display panel DP may include insulating layers PD-CL1, the end portion DL-E of the data line (refer to DL of FIG. 3A), a first pad PD1-1, a metal layer MTL-1, the first bump BP1, a first adhesive layer CF1, and a driving chip DC in a first area (refer to B1 of FIG. 5).

The first pad PD1-1 may be disposed on a third lower insulating layer 30 included in the insulating layers PD-CL.

The first pad PD1-1 may include a lower conductive pattern CL1, a first pattern SP1, an upper conductive pattern CL2, a second pattern SP2-1, and a first sub-pattern SUB1. That is, the first pad PD1-1 may further include a first sub-pattern SUB1 compared to the first pad PD1 described with reference to FIG. 6A. Accordingly, descriptions hereinafter will be focused on different features.

The second pattern SP2-1 may be disposed on the first pattern SP1 and the upper conductive pattern CL2. An upper surface S2U of the second pattern SP2-1 may have a predetermined curvature. In addition, the second pattern SP2-1 may have a thickness in the second direction DR2, which decreases as it goes upward in the third direction DR3 when viewed in the cross-section (e.g., as a distance from the insulating layers PD-CL1 increases, that is, in an upward direction). The second pattern SP2-1 may have a dome shape with a curved surface toward the third direction DR3. FIG. 7A shows the structure in which the second pattern SP2-1 has a semi-circular shape with the curved surface facing the third direction DR3 as a representative example, however, the shape of the second pattern SP2-1 should not be limited thereto or thereby.

A lower surface S2B-1 of the second pattern SP2-1 may cover at least a portion of an upper surface C2U of the upper conductive pattern CL2. When viewed in the cross-section of FIG. 7A, the lower surface S2B-1 of the second pattern SP2-1 may have the same width as a width of the upper surface C2U of the upper conductive pattern CL2, and thus, the lower surface S2B-1 of the second pattern SP2-1 may entirely cover the upper surface C2U of the upper conductive pattern CL2 (e.g., may cover an entirety of the upper surface C2U).

The first sub-pattern SUB1 may be disposed on the upper conductive pattern CL2. Referring to FIG. 7A, the first sub-pattern SUB1 may be disposed spaced apart from a right side surface SIS of the first pattern SP1 with the upper conductive pattern CL2 interposed therebetween when viewed in a plane substantially parallel to the base layer BL, however, the present disclosure should not be limited thereto or thereby. According to an embodiment, the first sub-pattern SUB1 may be disposed at a left side of the first pattern SP1.

When viewed in the cross-section, a width in the second direction DR2 of the first sub-pattern SUB1 may increase as it goes down (e.g., as a distance from the insulating layers PD-CLI decreases, that is, in a downward direction) . . . . As shown in FIG. 7A, the first sub-pattern SUB1 may have a triangular shape when viewed in the cross-section, however, the present disclosure should not be limited thereto or thereby.

The metal layer MTL-1 may further include a metal layer upper portion MU-1 covering the second pattern SP2-1, a first metal layer side portion MS1-1 disposed at a left side of the upper conductive pattern CL2 when viewed in the cross-section, a second metal layer side portion MS2-1 disposed at a right side of the upper conductive pattern CL2, and a metal layer tip portion MT-1 disposed on an upper insulating layer ISL-1 and protruded in the second direction DR2.

FIG. 7A shows a structure in which the metal layer tip portion MT is not formed in the second metal layer side portion MS2-1, however, the present disclosure should not be limited thereto or thereby. According to an embodiment, the metal layer tip portion MT may be formed in the second metal layer side portion MS2-1 to cover the upper insulating layer ISL-1.

However, even though the metal layer upper portion MU-1, the first metal layer side portion MS1-1, the second metal layer side portion MS2-1, and the metal layer tip portion MT may be defined, for the convenience of explanation, to respectively refer to portions of the metal layer MTL-1, the metal layer MTL-1 may have a continuous shape.

The metal layer MTL-1 may at least partially cover the second pattern SP2-1 and the first sub-pattern SUB1. Referring to FIG. 7A, the second metal layer side portion MS2-1 may cover a portion of the first sub-pattern SUB1. However, a position where the second metal layer side portion MS2-1 covers the first sub-pattern SUB1 should not be limited thereto or thereby.

A portion of the upper conductive pattern CL2, which covers a side surface of the first pattern SP1 in the second direction DR2, may be at least partially covered by the first metal layer side portion MS1-1. That is, an exposed portion of a side surface C2S of the upper conductive pattern CL2 may be exposed without being covered by the first sub-pattern SUB1, and the exposed portion of the side surface C2S of the upper conductive pattern CL2, which is not covered by the first sub-pattern SUB1, may be in contact with at least a portion of the metal layer MTL-1. FIG. 7A shows a first side surface exposed portion CLP1 where the side surface C2S of the upper conductive pattern CL2 is in contact with the metal layer MTL-1.

The second metal layer side portion MS2-1 may be in contact with at least a portion of the upper insulating layer ISL-1. Referring to FIG. 7A, a lower end of the second metal layer side portion MS2-1 may be in contact with the upper insulating layer ISL-1.

The upper insulating layer ISL-1 may be in contact with at least a portion of the metal layer MTL-1. Referring to FIG. 7A, the upper insulating layer ISL-1 may be in contact with a side surface of the first metal layer side portion MS1-1 and may be in contact with a lower surface of the second metal layer MS2-1, however, a position where the upper insulating layer ISL-1 is in contact with the metal layer MTL-1 should not be limited thereto or thereby.

The first sub-pattern SUB1 may be formed through the same process as the second pattern SP2. Accordingly, the first sub-pattern SUB1 may include the same material as the second pattern SP2. As an example, the first sub-pattern SUB1 may include a second photosensitive material, and the second photosensitive material may be a polymer with a negative photosensitivity.

Herein, various members or patterns including the polymer having a modulus which allows absorbing of the bonding pressure may be referred to as the aforementioned elements. Within a same display pad, the various members or patterns including the polymer having a modulus which allows absorbing of the bonding pressure may together define an elastic pattern, an impact-absorbing pattern, a bonding pressure-absorbing pattern, a compressible pattern or the like. In an embodiment, the first pattern SP1, the second pattern SP2 and/or a respective sub-pattern within the same display pad may together be considered a pressure-absorbing pattern of the same pad.

As shown in FIG. 7A, as the first pad PD1-1 includes the first sub-pattern SUB1, the first pad PD1-1 may have an asymmetrical shape when viewed in the cross-section.

The first sub-pattern SUB1 may support layers or patterns included in the first pad PD1-1 except the first sub-pattern SUB1, at one side of the first pad PD1-1. As an example, in a case where the first pattern SP1 has a relatively low modulus (e.g., elastic modulus), when the first sub-pattern SUB1 has a material with a modulus higher than that of the first pattern SP1, the first pattern SP1 may be prevented from being overly compressed or cracks may be prevented from occurring in the first pattern SP1 in the bonding presses. Accordingly, a structural stability of the first pad PD1-1 may be improved.

When bonding pressure from the first bump BP1 compresses the metal layer MTL-1, the bonding pressure may be transferred to the first metal layer side portion MS1-1 and the second metal layer side portion MS2-1 through the metal layer upper portion MU-1.

In this case, since the second metal layer side portion MS2-1 is spaced apart from the upper conductive pattern CL2 with the first sub-pattern SUB1 interposed therebetween, a portion of the second metal layer side portion MS2-1 may compress the first sub-pattern SUB1 and may be recessed deeper than the first metal layer side portion MS1-1. Accordingly, an anchor portion (e.g., the first anchor portion A1 at the right side) formed in the second metal layer side portion MS2-1 may be recessed deeper (e.g., further inward towards the first pattern SP1) than an anchor portion (e.g., the first anchor portion A1 at the left side) formed in the first metal layer side portion MS1-1. Therefore, the effect of the anchor portions distributing the bonding pressure within the first pad PD1-1 may increase.

Referring to FIG. 7B, a display panel DP may include insulating layers PD-CL2, an end portion DL-E of a data line (refer to DL of FIG. 3A), a first pad PD1-2, a metal layer MTL-2, a first bump BP1, a first adhesive layer CF1, and a driving chip DC in a first area B1 (refer to FIG. 5).

The first pad PD1-2 may include a lower conductive pattern CL1, a first pattern SP1, an upper conductive pattern CL2, a second pattern SP2-2, a first sub-pattern SUB1-2, and a second sub-pattern SUB2-2. That is, when compared with the first pad PD1-1 described with reference to FIG. 7A, the first pad PD1-2 may further include the second sub-pattern SUB2-2. Accordingly, descriptions hereinafter will be focused on different features between the display panels of FIGS. 7A and 7B.

When viewed in the cross-section, one side surface of the first pattern SP1 may be spaced apart from the first sub-pattern SUB1-2 with the upper conductive pattern CL2 interposed therebetween, and the other side surface of the first pattern SP1, which is opposite to the one side surface of the first pattern SP1, may be spaced apart from the second sub-pattern SUB2-2 with the upper conductive pattern CL2 interposed therebetween. Referring to FIG. 7B, a left side surface of the first pattern SP1 may be spaced apart from the second sub-pattern SUB2-2 with the upper conductive pattern CL2 interposed therebetween, and a right side surface of the first pattern SP1 may be spaced apart from the first sub-pattern SUB1-2 with the upper conductive pattern CL2 interposed therebetween.

At least portions of a side surface of the upper conductive pattern CL2 may be exposed respectively without being covered by the first sub-pattern SUB1-2 and the second sub-pattern SUB2-2, and the portions of the upper conductive pattern CL2, which are exposed respectively without being covered by the first sub-pattern SUB1-2 and the second sub-pattern SUB2-2, may be in contact with at least a portion of the metal layer MTL-2.

Referring to FIG. 7B, a second side surface exposed portion CLP2 exposed without being covered by the second sub-pattern SUB2-2 may be defined in a left side surface of the upper conductive pattern CL2, and a first side surface exposed portion CLP1 exposed without being covered by the first sub-pattern SUB1-2 may be defined in a right side surface of the upper conductive pattern CL2. Since the metal layer MTL-2 and the upper conductive pattern CL2 may be in contact with each other at the first side surface exposed portion CLP1 and the second side surface exposed portion CLP2, the metal layer MTL-2 and the upper conductive pattern CL2 may be at least partially in contact with each other and may be electrically connected to each other. The upper insulating layer ISL-2 may be in contact with at least a portion of the metal layer MTL-2.

As the first pad PD1-2 includes the first sub-pattern SUB1-2 and the second sub-pattern SUB2-2, the first pad PD1-2 may have a symmetrical structure when viewed in the cross-section, however, the present disclosure should not be limited thereto or thereby. When the first sub-pattern SUB1-2 and the second sub-pattern SUB2-2 have different shapes from each other, the first pad PD1-2 may have an asymmetrical structure when viewed in the cross-section.

The second sub-pattern SUB2-2 may be formed through the same process as the first sub-pattern SUB1-2. Accordingly, the second sub-pattern SUB2-2 may include the same material as the first sub-pattern SUB1-2. As an example, the second sub-pattern SUB2-2 may include a second photosensitive material, and the second photosensitive material may be a polymer with a negative photosensitivity. In an embodiment, the second sub-pattern SUB2-2 and the first sub-pattern SUB1-2 may be formed through the same process as the second pattern SP2-2. A lower surface S2B-2 and an upper surface S2U-2 of the second pattern SP2-2 may be the same as/similar to the lower surface S2B-1 and the upper surface S2U of the second pattern SP2-1.

The first and second sub-patterns SUB1-2 and SUB2-2 may support layers or patterns included in the first pad PD1-2 except the first and second sub-patterns SUB1-2 and SUB2-2 at both sides of the first pad PD1-2. As an example, in a case where the first pattern SP1 has a relatively low modulus (e.g., elastic modulus), when the first and second sub-patterns SUB1-2 and SUB2-2 have a material having a modulus higher than that of the first pattern SP1, the first pattern SP1 may be prevented from being overly compressed or cracks may be prevented from occurring in the first pattern SP1 in the bonding presses. Accordingly, a structural stability of the first pad PD1-2 may be improved.

When bonding pressure from the first bump BP1 compresses the metal layer MTL-2, the bonding pressure may be transferred to a metal layer side portion MS-2 through a metal layer upper portion MU-2.

In this case, since the metal layer side portions MS-2 are spaced apart from the upper conductive pattern CL2 with the first sub-pattern SUB1-2 and the second sub-pattern SUB2-2 interposed therebetween, portions of the metal layer side portions MS-2 may respectively compress the first sub-pattern SUB1-2 and the second sub-pattern SUB2-2 to form anchor portions in the metal layer MTL-2 which are deeply recessed inward toward the first pattern SP1. Accordingly, the effect of the anchor portions distributing the bonding pressure within the first pad PD1-2 may be improved.

Referring to FIG. 7C, a display panel DP may include insulating layers PD-CL3, an end portion DL-E of a data line (refer to DL of FIG. 3A), a first pad PD1-3, a first bump BP1, a first adhesive layer CF1, and a driving chip DC in a first area (refer to B1 of FIG. 5).

The insulating layers PD-CL3 may include a base layer BL, a barrier layer BRL, a first lower insulating layer 10, a second lower insulating layer 20, and a third lower insulating layer 30, which are sequentially stacked. Although not shown in FIG. 7C, the insulating layers PD-CL3 may further include an upper insulating layer (refer to ISL, ISL-1 and ISL-2 of aforementioned embodiments, for example).

The first pad PD1-3 may include a lower conductive pattern CL1, a first pattern SP1, an upper conductive pattern CL2-3, and a second pattern SP2-3.

The upper conductive pattern CL2-3 may be disposed to cover a portion of an upper surface S2U-3 of the second pattern SP2-3, a portion of a side surface SIS of the first pattern SP1, and at least a portion of an upper surface C1U of the lower conductive pattern CL1.

The second pattern SP2-3 may be disposed between the first pattern SP1 and the upper conductive pattern CL2-3. A lower surface S2B-3 of the second pattern SP2-3 may be in contact with an upper surface SIU-3 of the first pattern SP1. The upper surface S2U-3 of the second pattern SP2-3 may be covered by the upper conductive pattern CL2-3, such as having a same planar area as the upper conductive pattern CL2-3.

Referring to FIG. 7C, a width of the lower surface S2B-3 of the second pattern SP2-3 in the cross-section may be substantially the same as a width of the upper surface S1U-3 of the first pattern SP1 in the cross-section, however, the present disclosure should not be limited thereto or thereby. According to an embodiment, the width of the lower surface S2B-3 of the second pattern SP2-3 in the cross-section may be smaller than the width of the upper surface S1U-3 of the first pattern SP1. In this case, the upper conductive pattern CL2-3 may cover at least a portion of the upper surface SIU-3 of the first pattern SP1 and may expose a portion of the upper surface SIU-3 to outside the upper conductive pattern CL2-3.

The display panel DP may not include the metal layer MTL (refer to FIG. 6A). Accordingly, the deformation in the structure of the first pad PD1-3, which is caused when the first pattern SP1 and/or the second pattern SP2-3 is coupled with the metal layer MTL (refer to FIG. 6A), may be prevented.

The upper conductive pattern CL2-3 may be directly in contact with the first bump BP1. Therefore, a contact point CTP-3 may be formed between the upper conductive pattern CL2-3 and the first bump BP1.

The first bump BP1, the upper conductive pattern CL2-3, the lower conductive pattern CL1, and the end portion DL-E may be sequentially in contact (e.g., physically and/or electrically) with each other along a signal transmission path. Accordingly, the first bump BP1, the upper conductive pattern CL2-3, the lower conductive pattern CL1, and the end portion DL-E may be electrically connected to each other. Accordingly, a driving signal provided from the driving chip DC may be transferred to a light emitting element (refer to LD of FIG. 3B).

Referring to FIG. 7D, a display panel DP may include insulating layers PD-CL4, an end portion DL-E of a data line (refer to DL of FIG. 3A), a first pad PD1-4, a first bump BP1, a metal layer MTL-4, a first adhesive layer CF1, and a driving chip DC in a first area (refer to B1 of FIG. 5).

The display panel DP shown in FIG. 7D may further include the metal layer MTL-4 and an upper insulating layer ISL-4 as compared with the display panel shown in FIG. 7C.

The metal layer MTL-4 may include a metal layer upper portion MU-4 covering an upper conductive pattern CL2-3 and metal layer side portions MS-4 respectively disposed at left and right sides of the upper conductive pattern CL2-3. In addition, the metal layer MTL-4 may further include a metal layer tip portion MT-4 disposed on the upper insulating layer ISL-4 and protruded in the second direction DR2.

However, the metal layer upper portion MU-4, the metal layer side portion MS-4, and the metal layer tip portion MT-4 may be defined, for the convenience of explanation, to respectively refer to portions of the metal layer MTL-4, and the metal layer MTL-4 may have a continuous shape.

The metal layer MTL-4 may cover at least a portion of the upper conductive pattern CL2-3 and at least a portion of the upper insulating layer ISL-4. FIG. 7D shows a structure in which an upper surface C2U of the upper conductive pattern CL2-3 is in contact with the metal layer MTL-4 and the metal layer side portion MS-4 and the metal layer tip portion MT-4 are in contact with the upper insulating layer ISL-4.

The first bump BP1, the metal layer MTL-4, the upper conductive pattern CL2-3, a lower conductive pattern CL1, and the end portion DL-E may be sequentially in contact (e.g., physically and/or electrically) with each other along a signal transmission path. Accordingly, the first bump BP1, the metal layer MTL-4, the upper conductive pattern CL2-3, the lower conductive pattern CL1, and the end portion DL-E may be electrically connected to each other. Thus, a driving signal provided from the driving chip DC may be transmitted to a light emitting element (refer to LD of FIG. 3B).

Referring to FIG. 7E, a display panel DP may include insulating layers PD-CL5, an end portion DL-E of a data line (refer to DL of FIG. 3A), a first pad PD1-5, a first bump BP1, a metal layer MTL-5, a first adhesive layer CF1, and a driving chip DC in a first area (refer to B1 of FIG. 5).

The first pad PD1-5 may include a lower conductive pattern CL1, a first pattern SP1, an upper conductive pattern CL2-3, a second pattern SP2-3, a first sub-pattern SUB1-5, and a second sub-pattern SUB2-5.

The first pad PD1-5 shown in FIG. 7E may further include the first sub-pattern SUB1-5 and the second sub-pattern SUB2-5 as compared with the first pad PD1-3 shown in FIG. 7C. Accordingly, descriptions hereinafter will be focused on different features between the display panels of FIGS. 7C and 7E.

Descriptions on the first and second sub-patterns SUB1-5 and SUB2-5 may correspond to those of the first sub-pattern SUB1-2 and the second sub-pattern SUB2-2 with reference to FIG. 7B, and thus, details on the same elements will be omitted.

When viewed in the cross-section, one side surface of the first pattern SP1 may be spaced apart from the first sub-pattern SUB1-5 with the upper conductive pattern CL2-3 interposed therebetween, and the other side surface of the first pattern SP1, which is opposite to the one side surface, may be spaced apart from the second sub-pattern SUB2-5 with the upper conductive pattern CL2-3 interposed therebetween. Referring to FIG. 7E, a right side surface of the first pattern SP1 may be spaced apart from the second sub-pattern SUB2-5 with the upper conductive pattern CL2-3 interposed therebetween, and a left side surface of the first pattern SP1 may be spaced apart from the first sub-pattern SUB1-5 with the upper conductive pattern CL2-3 interposed therebetween.

When viewed in the cross-section, a width in the second direction DR2 of each of the first and second sub-patterns SUB1-5 and SUB2-5 may increase in a downward direction Referring to FIG. 7E, each of the first and second sub-patterns SUB1-5 and SUB2-5 may have a triangular shape when viewed in the cross-section, however, the present disclosure should not be limited thereto or thereby.

The first and second sub-patterns SUB1-5 and SUB2-5 may support components included in the first pad PD1-5 except the first and second sub-patterns SUB1-5 and SUB2-5 at both sides of the first pad PD1-5. As an example, in a case where the first pattern SP1 has a relatively low modulus (e.g., elastic modulus), when the first and second sub-patterns SUB1-5 and SUB2-5 include a material having a modulus higher than that of the first pattern SP1, the first pattern SP1 may be prevented from being overly compressed or cracks may be prevented from occurring in the first pattern SP1 in the bonding presses. Accordingly, a structural stability of the first pad PD1-5 may be improved.

When bonding pressure from the first bump BP1 compresses the metal layer MTL-5, the bonding pressure may be transferred to a metal layer side portion MS-5 through a metal layer upper portion MU-5.

In this case, since the metal layer side portions MS-5 are spaced apart from the upper conductive pattern CL2-3 with the first sub-pattern SUB1-5 or the second sub-pattern SUB2-5 interposed therebetween, a portion of the metal layer side portions MS-5 may compress the first sub-pattern SUB1-5 or the second sub-pattern SUB2-5 to form an anchor portion deeply recessed. Accordingly, the effect of the anchor portions distributing the bonding pressure may be improved.

In one or more embodiment, a display device DD (or a display panel DP) includes a base layer BL including a display area DP-DA including a light emitting element LD, and a non-display area DP-NDA which is adjacent to the display area DP-DA and includes a pad; and a signal line S-CL connecting the light emitting element LD to the pad. In the non-display area DP-NDA the pad among the signal pads DP-PC includes a lower conductive pattern CL1 on the base layer BL (with or without any one or more of the layers BRL to 30), a first pattern (e.g., the first pattern SP1) on the lower conductive pattern CL1 and including a first photosensitive material, an upper conductive pattern CL2 on the lower conductive pattern CL1 and overlapping the first pattern, and a second pattern (e.g., the second pattern SP2) on the first pattern and including a second photosensitive material different from the first photosensitive material.

In an embodiment, the pad may further include a sub-pattern (e.g., like SUB1 in FIG. 7A, and the like) facing a first side surface of the first pattern which is opposite to a second side surface of the first pattern. Within the pad the upper conductive pattern CL1 extends from the second side surface to the first side surface and between the first side surface and the sub-pattern, and the metal layer MTL extends along outer surfaces of each of the second pattern and the sub-pattern. Here, a portion of a side surface of the upper conductive pattern CL1 which extends along the first side surface of the first pattern is exposed outside the sub-pattern, and the metal layer MTL which extends along the outer surfaces of each of the second pattern and the sub-pattern contacts the portion of the side surface of the upper conductive pattern CL1.

In an embodiment, the pad may further include a first sub-pattern (e.g., like SUB1-2 in FIG. 7B) facing a first side surface of the first pattern, and a second sub-pattern (e.g., like SUB2-2 in FIG. 7B) facing a second side surface of the first pattern which is opposite to the first side surface. Within the pad, the upper conductive pattern CL1 extends between the first side surface and the first sub-pattern and between the second side surface and the second sub-pattern.

In an embodiment, the metal layer MTL of the pad has a cross-sectional shape which is deformable by a pressure (e.g., a bonding pressure) applied thereto through the bump in a direction toward the base layer BL and the shape of the metal layer MTL which is deformed by the pressure applied through the bump defines a recess (e.g., an anchor portion) in the metal layer side portion MS which is recessed in a direction toward the first pattern, the recess being under the metal layer side portion MS, along the thickness direction of the pad.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present invention shall be determined according to the attached claims.

What is claimed is:

1. A display device comprising:
a base layer comprising a display area and a non-display area adjacent to the display area;
lower insulating layers disposed on the base layer;
a light emitting element disposed in the display area;
a pad disposed in the non-display area; and
a signal line connected to the light emitting element and the pad, wherein the pad comprising:
a lower conductive pattern disposed on the lower insulating layers;
a first pattern disposed on the lower conductive pattern and comprising a first photosensitive material;
an upper conductive pattern disposed on the lower conductive pattern and overlapping at least a portion of the first pattern; and
a second pattern disposed on the first pattern and comprising a second photosensitive material different from the first photosensitive material.

2. The display device of claim 1, wherein
the first photosensitive material is a polymer with a negative photosensitivity, and
the second photosensitive material is a polymer with a positive photosensitivity or a metal material with the positive photosensitivity.

3. The display device of claim 1, wherein the second pattern comprises
an upper surface which is convexly curved in a direction away from the base layer, and
a width in a direction along the base layer, the width decreasing as a distance from the base layer increases.

4. The display device of claim 1, wherein
the second pattern is disposed on the upper conductive pattern, the upper conductive pattern is disposed between the first pattern and the second pattern, and the upper conductive pattern covers at least a portion of an upper surface of the first pattern, side surfaces of the first pattern, and an upper surface of the lower conductive pattern.

5. The display device of claim 4, further comprising:
a metal layer covering an upper surface of the second pattern and at least a portion of side surfaces of the upper conductive pattern; and
an upper insulating layer covering at least a portion of the metal layer and the upper conductive pattern, wherein the metal layer comprises a metal layer upper portion covering the second pattern and a metal layer side portion disposed on the side surface of the upper conductive pattern, and the metal layer side portion is in contact with the upper insulating layer.

6. The display device of claim 5, wherein the metal layer further comprises a metal layer tip portion disposed on the upper insulating layer and protruded in a direction in which the pads are arranged.

7. The display device of claim 5, further comprising:
a driving chip which provides a data signal to the light emitting element, the driving chip comprising a bump which contacts the metal layer,
wherein the driving chip is electrically connected to the pad through the bump, the metal layer, the upper conductive pattern and the lower conductive pattern.

8. The display device of claim 7, wherein
the metal layer of the pad has a cross-sectional shape which is deformable by a pressure applied thereto through the bump in a direction toward the base layer, and
the shape of the metal layer which is deformed by the pressure applied through the bump defines a recess in the metal layer side portion which is recessed in a direction toward the first pattern, the recess being under the metal layer side portion, along a thickness direction of the pad.

9. The display device of claim 7, wherein
a gap is defined between the driving chip and the pad, and
the gap is filled with a non-conductive adhesive.

10. The display device of claim 5, wherein within the pad, each of the upper conductive pattern and the lower conductive pattern comprises:
a first metal layer comprising titanium,
a second metal layer on the first metal layer and comprising aluminum, and
a third metal layer on the second metal layer and comprising titanium.

11. The display device of claim 5, wherein within the pad,
a portion of an upper surface of the upper conductive pattern is exposed to outside of the second pattern, and
the metal layer further extends along the portion of the upper surface of the upper conductive pattern.

12. The display device of claim 5, further comprising a sub-pattern, wherein the metal layer covers at least a portion of the second pattern and the sub-pattern, one side surface of the first pattern is disposed spaced apart from the sub-pattern with the upper conductive pattern interposed therebetween when viewed in a plane substantially parallel to the base layer, and a portion of the upper conductive pattern, which covers the other side surface opposite to the one side surface of the first pattern, is at least partially covered by the metal layer.

13. The display device of claim 12, wherein at least a portion of a side surface of the upper conductive pattern is exposed without being covered by the sub-pattern, and the at least a portion of the upper conductive pattern exposed without being covered by the sub-pattern is in contact with at least a portion of the metal layer.

14. The display device of claim 5, further comprising a first sub-pattern and a second sub-pattern, wherein one side surface of the first pattern is spaced apart from the first sub-pattern with the upper conductive pattern interposed therebetween when viewed in a cross-section, and the other side surface of the first pattern, which is opposite to the one side surface of the first pattern, is spaced apart from the second sub-pattern with the upper conductive pattern interposed therebetween when viewed in the cross-section.

15. The display device of claim 14, wherein one side surface of the upper conductive pattern and the other side surface of the upper conductive pattern, which is opposite to the one side surface of the upper conductive pattern, are at least partially exposed respectively without being covered by the first sub-pattern and the second sub-pattern, and portions of the upper conductive pattern exposed respectively without being covered by the first sub-pattern and the second sub-pattern are in contact with at least a portion of the metal layer.

16. The display device of claim 1, wherein the upper conductive pattern covers at least a portion of an upper surface of the second pattern, side surfaces of the first pattern, and an upper surface of the lower conductive pattern, and the second pattern is disposed between the first pattern and the upper conductive pattern.

17. The display device of claim 16, further comprising a bump that is directly in contact with the upper conductive pattern.

18. The display device of claim 16, further comprising a metal layer covering at least a portion of the upper conductive pattern.

19. The display device of claim 16, further comprising a first sub-pattern and a second sub-pattern, wherein one side surface of the first pattern is spaced apart from the first sub-pattern with the upper conductive pattern interposed therebetween when viewed in a cross-section, and the other side surface of the first pattern, which is opposite to the one side surface of the first pattern, is spaced apart from the second sub-pattern with the upper conductive pattern interposed therebetween when viewed in the cross-section.

20. The display device of claim 19, wherein each of the first sub-pattern and the second sub-pattern has a width in a direction along the base layer, the width increasing as a distance from the base layer decreases.
